(19) United States
(12) Patent Application Publication
(10) Pub. No.: US 2024/0248441 A1
(43) Pub. Date: Jul. 25, 2024

(54) HIGH-LEVEL SYNTHESIS DEVICE, HIGH-LEVEL SYNTHESIS METHOD, AND INFORMATION PROCESSING DEVICE

(71) Applicant: Mitsubishi Electric Corporation, Tokyo (JP)

(72) Inventors: Katsuhisa OGASAWARA, Tokyo (JP); Nobuo CHIDA, Tokyo (JP); Haruhiko TAKEYAMA, Tokyo (JP)

(73) Assignee: Mitsubishi Electric Corporation, Tokyo (JP)

(21) Appl. No.: 18/289,902

(22) PCT Filed: May 14, 2021
(86) PCT No.: PCT/JP2021/018343

§ 371 Date: Nov. 8, 2023

(51) Int. Cl. G05B 15/02

(52) U.S. Cl. CPC G05B 15/02

(57) ABSTRACT

A high-level synthesis processing unit of the high-level synthesis device according to the present disclosure performs high-level synthesis processing of generating the hardware descriptions based on specification descriptions including the behavioral description, a high-level synthesis specification description, and an execution trace specification description. The hardware descriptions include a behavioral processing hardware description, an execution trace mechanism unit description, and an execution trace mechanism common unit description. The execution trace specification description is described to correspond to the behavioral description.

### TECHNICAL FIELD

The present disclosure relates to a high-level synthesis device to generate hardware descriptions from specification descriptions including a behavioral description, a high-level synthesis method, and an information processing device implemented by the hardware descriptions.

### BACKGROUND ART

An automatic control system is typically a system to perform recognition, determination, and control through coordination and integration of a plurality of functions. For example, an autonomous driving system includes an autonomous driving controller to generate an optimum control parameter from an ambient condition and an engine controller, a brake controller, and a steering controller to respectively perform engine control, brake control, and steering control of a vehicle.

The higher an autonomy level, such as an autonomous driving level, becomes, the more processing performance is required for the automatic control system. A range of responsibility the automatic control system should take also increases with increasing autonomy level. For example, autonomous driving has an autonomous driving level defined by the Society of Automotive Engineers (SAE) International, and, with increasing the level, the range of responsibility the system should take increases.

Specifically, in a case where an anomaly occurs anywhere in the autonomous driving system, autonomous driving can no longer be continued, so that maintenance operation until transition to a safety-secured state or transition operation to a safe state is required. In addition, recording of processing information and internal behavior during system run-time is required.

A high-level synthesis method can be used for processing content described by software for the system to satisfy necessary processing performance. The use of the high-level synthesis method allows for construction of a dedicated hardware circuit compatible with software and mounting of the constructed dedicated hardware circuit on the system.

On the other hand, the system is sometimes constructed using a functional safety mechanism to secure safety when a failure occurs. Representative examples of the functional safety mechanism include (1) a monitoring mechanism, (2) an error detection/correction function, (3) a majority vote mechanism, and (4) a multiple redundancy system.

In the system in which the dedicated hardware circuit is constructed using the high-level synthesis method, however, a hardware description generated by the high-level synthesis method is not available for acquisition and recording of hardware processing information associated with a behavioral description by software. Furthermore, the hardware description generated by the high-level synthesis method is optimized, so that acquisition and recording of information associated with the behavioral description by software are not easy.

To address such a problem, Patent Document 1 proposes a high-level synthesis method of generating a hardware description into which a functional safety mechanism has been inserted. Patent Document 2 proposes a high-level synthesis method of generating a hardware description trace description to acquire transition history of a signal in a hardware description.

### PRIOR ART DOCUMENTS

### Patent Documents

Patent Document 1: Japanese Patent Application Laid-Open No. 2020-16050
Patent Document 2: Japanese Patent Application Laid-Open No. 2006-338586

### SUMMARY

### Problem to be Solved by the Invention

Technology disclosed in Patent Document 1 is the high-level synthesis method of inserting the functional safety mechanism into the hardware description to be generated but is not intended for acquisition and recording of information when processing of hardware associated with a behavioral description by software is performed. Examples of the software include a C language and a C++ language.

Technology disclosed in Patent Document 2 is intended for behavioral verification due to simulation of the hardware description and is not intended for acquisition and recording of information during hardware execution as in Patent Document 1. Thus, there has been a problem in that even a combination of technology disclosed in Patent Document 1 and technology disclosed in Patent Document 2 does not enable acquisition and recording of information during execution of the hardware circuit associated with the behavioral description.

That is to say, an information processing device obtained by hardware implementation using a hardware description generated by a conventional high-level synthesis method has a problem in that it cannot have an execution trace function corresponding to the behavioral description.

The present disclosure has been conceived to solve a problem as described above, and it is an object of the present disclosure to obtain a high-level synthesis device to generate hardware descriptions enabling an information processing device obtained by hardware implementation to have an execution trace function corresponding to a behavioral description.

### Means to Solve the Problem

A high-level synthesis device according to the present disclosure includes: a specification description providing unit to provide specification descriptions including a behavioral description indicating functional logic; and a high-level synthesis processing unit to perform high-level synthesis processing of generating hardware descriptions based on the specification descriptions, the hardware descriptions including a behavioral processing hardware description for an information processing device obtained by hardware implementation of the functional logic indicated by the behavioral description, wherein the specification descriptions further include an execution trace specification description for trace processing described to correspond to the behavioral description, in the high-level synthesis processing, an execution trace hardware description describing an execution trace function to perform the trace processing is further generated based on the behavioral description and the execution trace specification description, and the hardware descriptions include the execution trace hardware description.

### Effects of the Invention

The high-level synthesis processing unit of the high-level synthesis device according to the present disclosure generates, as a portion of the hardware descriptions, the execution trace hardware description describing the execution trace function to perform the trace processing based on the behavioral description and the execution trace specification description.

An information processing device obtained by hardware implementation using the hardware descriptions generated by the high-level synthesis device according to the present disclosure can thus have the execution trace function corresponding to the behavioral description.

The objects, features, aspects and advantages of the present disclosure will become more apparent from the following detailed description when taken in conjunction with the accompanying drawings.

### BRIEF DESCRIPTION OF DRAWINGS

FIG. 1 is a block diagram showing a configuration of a high-level synthesis device in Embodiment 1 according to the present disclosure.

FIG. 2 is an illustration (part 1) of an example of content of an execution trace specification description in Embodiment 1 shown in tabular form.

FIG. 3 is an illustration (part 2) of the example of the content of the execution trace specification description in Embodiment 1 shown in tabular form.

FIG. 4 is an illustration of specific examples of a behavioral description, a high-level synthesis specification description, and the execution trace specification description.

FIG. 5 is a flowchart showing processing procedures of high-level synthesis processing performed by a high-level synthesis processing unit in Embodiment 1.

FIG. 6 is a flowchart showing processing procedures of execution trace extension processing performed by an execution trace extension processing unit in Embodiment 1.

FIG. 7 is an illustration of a specific example of a control data flow graph (CDFG) created by a CDFG creation processing unit in Embodiment 1.

FIG. 8 is an illustration of a specific example of a CDFG with execution trace extension created by a CDFG execution trace extension processing unit in Embodiment 1.

FIG. 9 is an illustration of a specific example of a scheduled CDFG created by a scheduling processing unit in Embodiment 1.

FIG. 10 is an illustration of a specific example of a bound CDFG created by a binding processing unit in Embodiment 1.

FIG. 11 is a flowchart showing processing procedures of maximum window time calculation processing performed by an execution trace maximum window time calculation unit in Embodiment 1.

FIG. 12 is an illustration of a specific example of a state control machine generated by a state control machine generation unit in Embodiment 1.

FIG. 13 is a flowchart (part 1) showing processing procedures of execution trace related information generation processing performed by an execution trace mechanism generation unit in Embodiment 1.

FIG. 14 is a flowchart (part 2) showing the processing procedures of the execution trace related information generation processing performed by the execution trace mechanism generation unit in Embodiment 1.

FIG. 15 is a flowchart showing processing procedures of execution trace mechanism unit generation processing performed by the execution trace mechanism generation unit.

FIG. 16 is a block diagram showing a configuration of an execution trace mechanism unit description and an execution trace mechanism common unit description in Embodiment 1.

FIG. 17 is a block showing a configuration of an information processing device implemented using hardware descriptions generated by the high-level synthesis device in Embodiment 1.

FIG. 18 is a flowchart (part 1) showing processing procedures of trace processing performed by an execution trace mechanism unit HW circuit of the information processing device.

FIG. 19 is a flowchart (part 2) showing the processing procedures of the trace processing performed by the execution trace mechanism unit HW circuit of the information processing device.

FIG. 20 is a flowchart showing processing content of data transfer processing performed by a memory transfer unit of the information processing device.

FIG. 21 is an illustration of an example of content of an execution trace specification description in Embodiment 2 according to the present disclosure shown in tabular form.

FIG. 22 is a block diagram showing a configuration of a processing circuit corresponding to the high-level synthesis processing unit of the high-level synthesis device.

FIG. 23 is a block diagram showing another example of the configuration of the processing circuit corresponding to the high-level synthesis processing unit.

### DESCRIPTION OF EMBODIMENTS

### Embodiment 1

### (Overall Configuration)

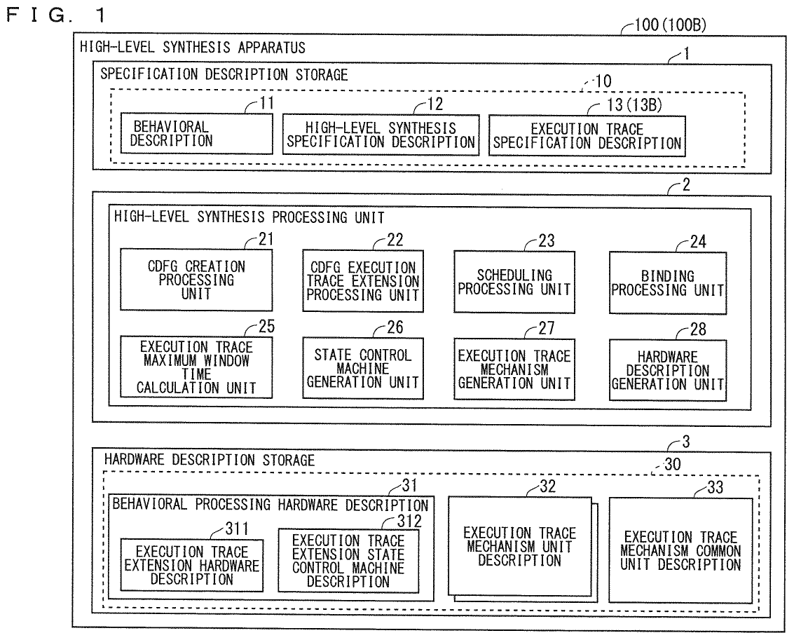

FIG. 1 is a block diagram showing a configuration of a high-level synthesis device 100 in Embodiment 1 according to the present disclosure. The high-level synthesis device 100 at least includes a specification description storage 1, a high-level synthesis processing unit 2, and a hardware description storage 3.

The specification description storage 1 stores specification descriptions 10 used by the high-level synthesis processing unit 2 and functions as a specification description providing unit to provide the specification descriptions 10 to the high-level synthesis processing unit 2.

The high-level synthesis processing unit 2 performs high-level synthesis processing based on the specification descriptions 10 provided by the specification description storage 1 to generate hardware descriptions 30. The hardware descriptions 30 are stored in the hardware description storage 3.

The specification descriptions 10 include a behavioral description 11, a high-level synthesis specification description 12, and an execution trace specification description 13.

The behavioral description 11 is a description indicating functional logic of a hardware circuit to be created. The behavioral description 11 may be described using software, such as C and C++. The behavioral description 11 may be described to specify a portion of the description by software to be the hardware circuit by the high-level synthesis processing. For example, the behavioral description 11 described to specify a function described by software as the hardware circuit may be used.

The high-level synthesis specification description 12 is a description indicating content defining constraints on high-level synthesis, such as the hardware circuit created by high-level synthesis, frequency of the hardware circuit, a timing of performing each operation, a hardware resource to be used, and the area of the hardware circuit.

The execution trace specification description 13 is a description to perform extension to perform trace processing of tracing execution-time information during hardware operation in the hardware descriptions 30 generated by high-level synthesis. That is to say, the execution trace specification description 13 is a description indicating a specification necessary for generation of a hardware function to acquire and record trace information as the execution-time information in the trace processing.

The high-level synthesis processing unit 2 includes a control data flow graph (hereinafter also abbreviated to “CDFG”) creation processing unit 21, a CDFG execution trace extension processing unit 22, a scheduling processing unit 23, a binding processing unit 24, an execution trace maximum window time calculation unit 25, a state control machine generation unit 26, an execution trace mechanism generation unit 27, and a hardware description generation unit 28.

The hardware descriptions 30 stored in the hardware description storage 3 include a behavioral processing hardware description 31, an execution trace mechanism unit description 32, and an execution trace mechanism common unit description 33. Based on the hardware descriptions 30, the information processing device obtained by hardware implementation of the functional logic indicated by the behavioral processing hardware description 31 can be implemented.

The hardware descriptions 30 are a collection of descriptions described in a hardware description language to achieve a hardware logic circuit. Examples of the hardware description language include a hardware description language (HDL), Verilog, and a VHDL.

### (Processing Circuit)

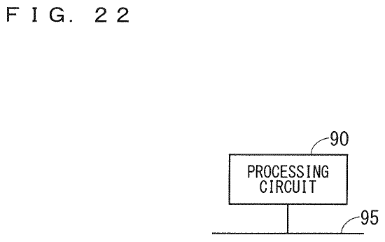

FIG. 22 is a block diagram showing a configuration of a processing circuit 90 corresponding to the high-level synthesis processing unit 2 of the high-level synthesis device 100. Functions of the high-level synthesis processing unit 2 are achieved by the processing circuit 90 shown in FIG. 22. That is to say, the processing circuit 90 functions as a circuit including the high-level synthesis processing unit 2.

In a case where the processing circuit 90 is dedicated hardware, the processing circuit 90 is a single circuit, a composite circuit, a programmed processor, a parallel programmed processor, an application specific integrated circuit (ASIC), a field-programmable gate array (FPGA), or a circuit as a combination of them, for example. The functions 21 to 28 of the high-level synthesis processing unit 2 may individually be achieved by a plurality of processing circuits or may collectively be achieved by a single processing circuit.

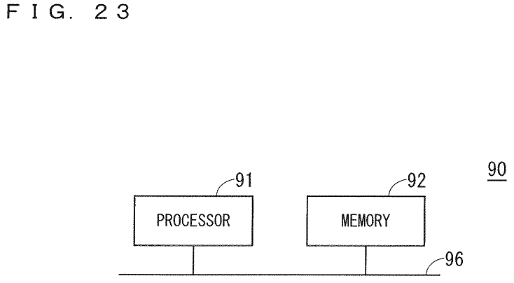

FIG. 23 is a block diagram showing another example of the configuration of the processing circuit corresponding to the high-level synthesis processing unit 2. As shown in the figure, the processing circuit 90 includes a processor 91, a memory 92, and a bus 96 to be a data transfer path between the processor 91 and the memory 92. The processor 91 executes a program stored in the memory 92 to achieve the functions 21 to 28 of the high-level synthesis processing unit 2. For example, the processor 91 executes software or firmware described as the program to achieve the functions 21 to 28. That is to say, the high-level synthesis device 100 includes the memory 92 to store the program, the processor 91 to execute the program, and the bus 96 for data transfer between the memory 92 and the processor 91.

The program is to cause a computer to perform processing procedures or processing methods for the functions 21 to 28 of the high-level synthesis processing unit 2.

Examples of the processor 91 include a central processing unit, a processing unit, an operational unit, a microprocessor, a microcomputer, and a digital signal processor (DSP). An example of the memory 92 includes a nonvolatile or volatile semiconductor memory, such as a random access memory (RAM), a read only memory (ROM), a flash memory, an erasable programmable read only memory (EPROM), and an electrically erasable programmable read only memory (EEPROM). As the memory 92, any storage medium to be used in the future, such as a magnetic disk, a flexible disk, an optical disc, a compact disc, a mini disc, and a DVD, may be used.

The specification description storage 1 and the hardware description storage 3 can be achieved by the memory 92 or an unillustrated external storage device connected to the bus 96. The specification descriptions 10 are classified as data stored in the specification description storage 1, and the hardware descriptions 30 are classified as data stored in the hardware description storage 3.

Some of the functions of the units 21 to 28 of the above-mentioned high-level synthesis processing unit 2 may be achieved by the dedicated hardware, and the other functions may be achieved by software or firmware. As described above, the processing circuit 90 achieves the above-mentioned functions by hardware, software, firmware, or a combination of them.

### (Configuration of Each Unit)

The CDFG creation processing unit 21 receives the behavioral description 11 in the specification descriptions 10 from the specification description storage 1, optimizes the functional logic described by the behavioral description 11, extracts a control flow and a data flow, and mainly creates a control data flow graph (CDFG). The CDFG as intermediate data created by the CDFG creation processing unit 21 may be stored in a storage region of a system in which the high-level synthesis device 100 operates. For example, the memory 92 shown in FIG. 23 may have the storage region.

The CDFG execution trace extension processing unit 22 receives the execution trace specification description 13 in the specification descriptions 10 from the specification description storage 1 and further receives the CDFG created by the CDFG creation processing unit 21. The CDFG execution trace extension processing unit 22 provides an execution trace extension function to the CDFG created by the CDFG creation processing unit 21 based on the execution trace specification description 13 to generate a CDFG with execution trace extension. The CDFG with execution trace extension as intermediate data may be stored in the storage region of the system in which the high-level synthesis device 100 operates.

The scheduling processing unit 23 receives the high-level synthesis specification description 12 in the specification descriptions 10 from the specification description storage 1 and further receives the CDFG with execution trace extension generated by the CDFG execution trace extension processing unit 22. The scheduling processing unit 23 determines an execution cycle of operation processing in the CDFG with execution trace extension based on the constraints specified by the high-level synthesis specification description 12 to generate a scheduled CDFG. The scheduled CDFG as intermediate data may be stored in the storage region of the system in which the high-level synthesis device 100 operates.

The binding processing unit 24 receives the high-level synthesis specification description 12 in the specification descriptions 10 from the specification description storage 1 and further receives the scheduled CDFG generated by the scheduling processing unit 23. The binding processing unit 24 performs mapping of an operational unit, a register, and the like to a data path in the scheduled CDFG based on the constraints specified by the high-level synthesis specification description 12 to generate a bound CDFG. The bound CDFG as intermediate data may be stored in the storage region of the system in which the high-level synthesis device 100 operates.

The operational unit, the register, and the like described above are hardware resources. That is to say, the binding processing unit 24 allocates a hardware resource to the scheduled CDFG to acquire the bound CDFG.

The execution trace maximum window time calculation unit 25 receives the bound CDFG generated by the binding processing unit 24. The execution trace maximum window time calculation unit 25 calculates execution trace maximum window time (hereinafter also simply abbreviated to “maximum window time”) for the bound CDFG.

The maximum window time is maximum time to perform the trace processing using hardware without affecting behavioral processing performed by the information processing device to be the hardware circuit corresponding to the functional logic descried by the behavioral description 11. The maximum window time as intermediate data may be stored in the storage region of the system in which the high-level synthesis device 100 operates.

The state control machine generation unit 26 receives the scheduled CDFG generated by the scheduling processing unit 23. The scheduled CDFG is divided into a plurality of control states as will be described below.

The state control machine generation unit 26 generates a state control machine to control state transition between the plurality of control states of the scheduled CDFG. The state control machine as intermediate data may be stored in the storage region of the system in which the high-level synthesis device 100 operates.

The execution trace mechanism generation unit 27 receives the execution trace specification description 13 in the specification descriptions 10 from the specification description storage 1. The execution trace mechanism generation unit 27 further receives the bound CDFG generated by the binding processing unit 24, the maximum window time generated by the execution trace maximum window time calculation unit 25, and the state control machine generated by the state control machine generation unit 26.

The execution trace mechanism generation unit 27 generates an execution trace extension state control machine obtained by providing the execution trace extension function to the state control machine, an execution trace mechanism unit, and an execution trace mechanism common unit based on the execution trace specification description 13, the bound CDFG, the maximum window time, and the state control machine. The execution trace mechanism unit and the execution trace mechanism common unit will be described in detail below.

The execution trace extension state control machine, the execution trace mechanism unit, and the execution trace mechanism common unit as intermediate data may be stored in the storage region of the system in which the high-level synthesis device 100 operates.

The hardware description generation unit 28 receives the bound CDFG generated by the binding processing unit 24 and the execution trace extension state control machine, the execution trace mechanism unit, and the execution trace mechanism common unit generated by the execution trace mechanism generation unit 27.

The hardware description generation unit 28 generates the hardware descriptions 30 based on the bound CDFG, the execution trace extension state control machine, the execution trace mechanism unit, and the execution trace mechanism common unit.

As described above, the hardware descriptions 30 include the behavioral processing hardware description 31, the execution trace mechanism unit description 32, and the execution trace mechanism common unit description 33. The execution trace mechanism unit description 32 and the execution trace mechanism common unit description 33 are execution trace hardware descriptions indicating an execution trace function to perform the trace processing.

The behavioral processing hardware description 31 includes an execution trace extension hardware description 311 and an execution trace extension state control machine 312.

The execution trace extension hardware description 311 is a description obtained by adding, to a hardware description (hereinafter also abbreviated to a “HW description”) corresponding to the functional logic in the behavioral description 11, a HW description corresponding to an execution trace extension portion.

The execution trace extension state control machine 312 is an execution trace extension state control machine description corresponding to the execution trace extension state control machine. That is to say, the execution trace extension state control machine 312 is a HW description created by the hardware description generation unit 28 based on the execution trace extension state control machine as the intermediate data generated by the execution trace mechanism generation unit 27.

The execution trace mechanism unit description 32 is a HW description corresponding to the execution trace mechanism unit. That is to say, the execution trace mechanism unit description 32 is a HW description created by the hardware description generation unit 28 based on the execution trace mechanism unit as the intermediate data generated by the execution trace mechanism generation unit 27.

Similarly, the execution trace mechanism common unit description 33 is a HW description corresponding to the execution trace mechanism common unit. That is to say, the execution trace mechanism common unit description 33 is a HW description created by the hardware description generation unit 28 based on the execution trace mechanism common unit as the intermediate data generated by the execution trace mechanism generation unit 27.

As described above, the hardware descriptions 30 are a collection of HW descriptions including the behavioral processing hardware description 31, the execution trace mechanism unit description 32, and the execution trace mechanism common unit description 33.

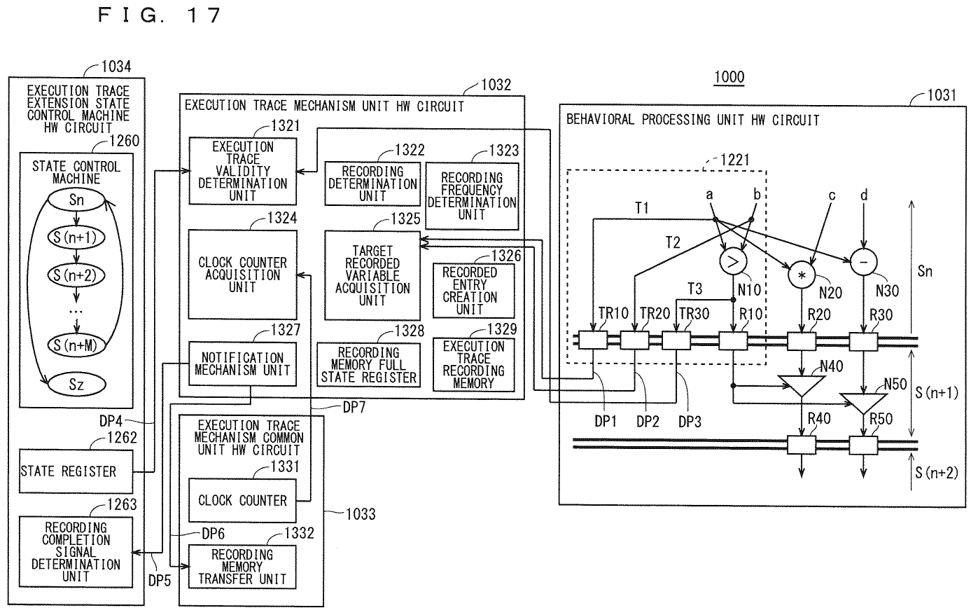

An information processing device 1000, which will be described below with reference to FIG. 17, can thus be formed by performing logic synthesis and place-and-route from the behavioral processing hardware description 31, the execution trace mechanism unit description 32, and the execution trace mechanism common unit description 33 in the hardware descriptions 30 stored in the hardware description storage 3. That is to say, a hardware circuit implemented by the various HW descriptions 31 to 33 in the hardware descriptions 30 is the information processing device 1000 having the execution trace function corresponding to the behavioral description 11.

### (Execution Trace Specification Description 13)

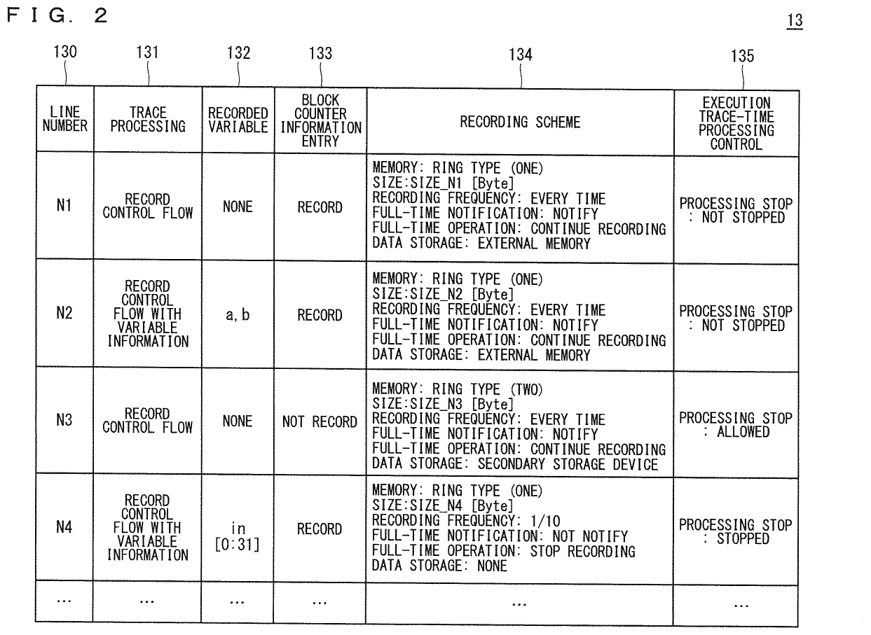

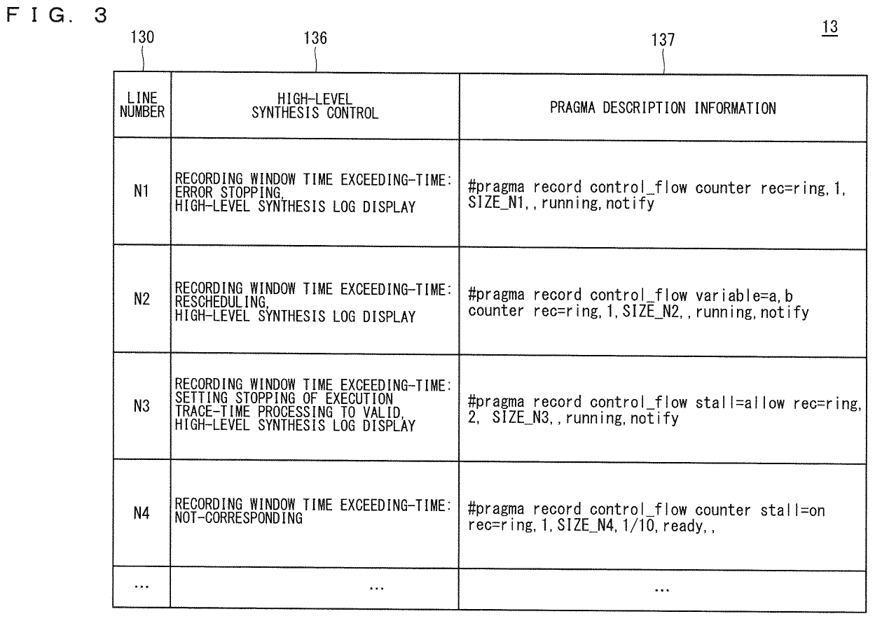

FIGS. 2 and 3 are illustrations of an example of content of the execution trace specification description 13 in Embodiment 1 according to the present disclosure shown in tabular form. The execution trace specification description 13 is assumed to be described so that a behavioral step to be unit behavior indicated by the behavioral description 11 corresponds to a line number.

The behavioral description 11 is a description by software (e.g., the C language and the C++ language), so that the unit behavior may be considered to correspond to one statement by a software description. While one statement by the software description is normally described in each line, one statement by the software description may be formatted to be in each line by a code formatter and the like as conventional technology.

As shown in these figures, the execution trace specification description 13 has a line number entry 130 as trace position identification information identifying a trace position in the behavioral description 11 by the line number. The line number identified by the line number entry 130 as the trace position identification information is defined as a trace target line number. Line numbers N1, N2, N3, N4, . . . are shown as trace target line numbers in FIGS. 2 and 3.

As shown in FIGS. 2 and 3, a trace processing entry 131, a recorded variable entry 132, a clock counter information entry 133, a recording scheme entry 134, an execution trace-time processing control entry 135, a high-level synthesis control entry 136, and a pragma description entry 137 are provided to correspond to the trace target line number.

That is to say, the execution trace specification description 13 is described to correspond to the unit behavior indicated by the behavioral description 11.

The trace processing entry 131 is trace processing information indicating an outline of content of the trace processing. As examples of the trace processing entry 131 shown in FIG. 2, “RECORD CONTROL FLOW” and “RECORD CONTROL FLOW WITH VARIABLE INFORMATION” are shown.

“RECORD CONTROL FLOW” means that the trace target line number in the behavioral description 11 is recorded as the execution-time information in a case where a corresponding hardware circuit is executed, and “RECORD CONTROL FLOW WITH VARIABLE INFORMATION” means that, in a case where unit behavior corresponding to the trace target line number in the behavioral description 11 is executed, content of a variable specified by the recorded variable entry 132 is added to the trace target line number and recorded as the execution-time information for recording of a control flow with variable information.

As described above, the trace processing entry 131 is the trace processing information indicating content of processing of recording the trace information acquired when the information processing device implemented by the hardware descriptions 30 performs the trace processing.

The recorded variable entry 132 specifies a variable in the behavioral description 11 recorded as the trace information when the trace processing is performed. In a case where no variable is recorded, the variable may be specified as “NONE”. In a case where data of an array in the behavioral description 11 is recorded, a symbol of the recorded array and a range of array indices may be specified. An example of the recorded variable entry 132 shown in FIG. 2 indicates that the recorded variable corresponding to the line number N2 as the trace target line number includes a variable a and a variable b, and the recorded variable corresponding to the line number N4 as the trace target line number includes indices 0 to 31 in an array in.

As described above, the recorded variable entry 132 is recorded variable information indicating the variable recorded as the trace information.

The clock counter information entry 133 specifies whether to record a clock count value of a clock counter as the trace information when the trace processing is performed. An example of the clock counter information entry 133 in FIG. 2 shows “RECORD” indicating that clock counter information is recorded and “NOT RECORD” indicating that the clock counter information is not recorded.

As described above, the clock counter information entry 133 is clock counter specifying information indicating whether to record the clock count value as the trace information.

The recording scheme entry 134 specifies a method of controlling processing of recording the trace information when the trace processing is performed. That is to say, the recording scheme entry 134 is recording scheme information indicating the method of controlling the processing of recording the trace information.

The recording scheme entry 134 includes a memory entry, a size entry, a recording frequency entry, a full-time notification entry, a full-time operation entry, and a data storage entry.

The memory entry indicates types and the number of execution trace recording memories to record the trace information when the trace processing is performed, and the size entry indicates a size of each execution trace recording memory.

The recording frequency entry indicates frequency of recording of the trace information. That is to say, the recording frequency entry specifies the frequency of recording of the execution-time information in a case where the unit behavior corresponding to the trace target line number in the behavioral description 11 is executed. For example, in a case where the recording frequency entry specifies 1/10 as in the recording scheme entry 134 corresponding to the line number N4, it means that recording is performed once when processing corresponding to the line number N4 is performed ten times.

The full-time notification entry indicates whether to provide notification when the execution trace recording memory is in a memory full state. That is to say, the full-time notification entry indicates whether to output a memory full signal as a notification signal in the memory full state.

The full-time operation entry indicates trace control content when the execution trace recording memory is in the memory full state. That is to say, the full-time operation entry indicates whether to continue recording processing in the memory full state.

The data storage entry indicates a data storage destination to store the trace information in the execution trace recording memory. That is to say, the data storage entry specifies a device to secondarily store data in the execution trace recording memory as the data storage destination.

In a case where the full-time notification entry indicates “NOTIFY”, the memory full signal is generated when any one of at least one memory specified by the memory entry is in the memory full state. In an example of the recording scheme entry 134 shown in FIG. 2, the memory entry indicates a ring type of returning a recording position to the head to continue recording when the memory is in the memory full state. As the data storage destination indicated by the data storage entry, an external memory other than the recording memory that is not targeted for hardware description and a secondary storage device are indicated. The RAM and the like having a relatively fast response speed are considered as the external memory, and a hard disk and the like having relatively large capacity are considered as the secondary storage device.

As described above, the recording scheme entry 134 indicates a method of controlling the processing of recording the trace information when the trace processing is performed.

The high-level synthesis device 100 in Embodiment 1 can generate the hardware descriptions 30 for the information processing device having a trace function with various recording schemes based on the recording scheme entry 134 as the recording scheme information included in the execution trace specification description 13.

The execution trace-time processing control entry 135 specifies content of control of processing of operation performed by the information processing device implemented by the hardware descriptions 30 during acquisition and recording of the trace information when the trace processing is performed.

The execution trace-time processing control entry 135 includes a processing stop entry specifying whether to stop operation performed by the information processing device. That is to say, the execution trace-time processing control entry 135 is execution trace-time processing control information indicating whether to stop processing performed by the information processing device when the trace processing is performed.

The high-level synthesis control entry 136 specifies a method of controlling the high-level synthesis processing performed by the high-level synthesis processing unit 2. The high-level synthesis control entry 136 includes a recording window time exceeding-time entry. The recording window time exceeding-time entry specifies content of processing performed by the high-level synthesis processing unit 2 in a case where it is determined that a processing cycle as time required for the execution trace mechanism unit to perform processing exceeds the execution trace maximum window time calculated by the execution trace maximum window time calculation unit 25.

In an example of the high-level synthesis control entry 136 shown in FIG. 3, error stopping of the high-level synthesis processing unit 2, rescheduling processing of causing the scheduling processing unit 23 to perform scheduling processing again, and high-level synthesis log display to display a log of the high-level synthesis processing are described as the recording window time exceeding-time entry. In a case where the processing stop entry in the execution trace-time processing control entry 135 indicates that processing is “STOPPED”, the recording window time exceeding-time entry is described as not-corresponding. With the rescheduling processing, the binding processing unit 24, the execution trace maximum window time calculation unit 25, the state control machine generation unit 26, the execution trace mechanism generation unit 27, and the hardware description generation unit 28 as processing units downstream of the scheduling processing unit 23 are to perform processing again.

As described above, the high-level synthesis control entry 136 is high-level synthesis control information indicating content of processing performed in a case where the processing cycle as the trace time to perform the trace processing exceeds the maximum window time.

The pragma description entry 137 indicates pragma description information corresponding to the execution trace specification description for each trace target line number. That is to say, the pragma description entry 137 is information indicating content of the entries 131 to 136 corresponding to the trace target line number in the line number entry 130. Content of the pragma description information may be obtained by simplifying content of the entries 131 to 136 in a case where the pragma description information is described in the pragma description entry 137 as a reference example.

### (Behavioral Description, High-Level Synthesis Specification Description, and Execution Trace Specification Description)

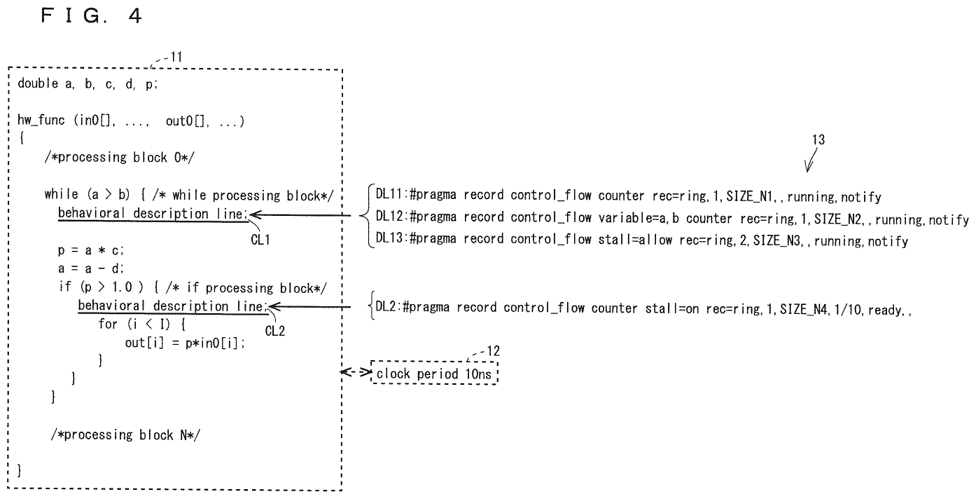

FIG. 4 is an illustration of specific examples of the behavioral description 11, the high-level synthesis specification description 12, and the execution trace specification description 13. FIG. 4 shows an example of the behavioral description 11, an example of the high-level synthesis specification description 12, and an example of the pragma description entry 137 in the execution trace specification description 13 corresponding to the example of the behavioral description 11 in Embodiment 1 according to the present disclosure. The example of the behavioral description 11 describes an example of a hardware function by a software description in the C language. The pragma description entry 137 is shown to correspond to each of behavioral description lines CL1 and CL2 in the example of the behavioral description 11. Furthermore, the example of the high-level synthesis specification description 12 describes constraints on a clock period.

FIG. 4 shows a state of setting at least one of trace descriptions DL11 to DL13 for the behavioral description line CL1 as the trace target line number and a state of setting a trace description DL2 for the behavioral description line CL2 as the trace target line number. The high-level synthesis specification description 12 indicates 10 ns as the clock period to execute the functional logic in the behavioral description 11.

Content of description of the trace description DL12 will be described below. “#pragma record” indicates a pragma relating to trace recording, “control flow” indicates recording of the control flow, “variable=a,b” indicates recorded variables a and b, and “counter” indicates recording of the clock count value. “rec=ring,1, SIZE_N2, running, notify” indicates that the execution trace recording memory is of the ring type, the number of execution trace recording memories is one, the size of the execution trace recording memory is N2, the frequency of recording is every time, memory full-time operation is continue, and notification is provided in the memory full state.

“control flow” corresponds to the trace processing entry 131, “variable=a,b” corresponds to the recorded variable entry 132, “counter” corresponds to the clock counter information entry 133, and “rec=ring,1, SIZE_N2, running, notify” corresponds to the recording scheme entry 134. In a case where the pragma description entry 137 is described completely, descriptions corresponding to the execution trace-time processing control entry 135 and the high-level synthesis control entry 136 are further required.

### (High-Level Synthesis Processing)

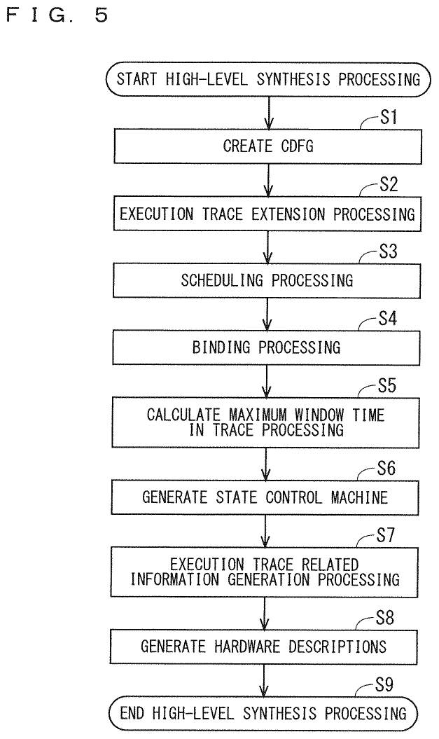

FIG. 5 is a flowchart showing processing procedures of the high-level synthesis processing performed by the high-level synthesis processing unit 2 in Embodiment 1 according to the present disclosure.

The high-level synthesis processing unit 2 starts the high-level synthesis processing by being provided with the specification descriptions 10 stored in the specification description storage 1 as the specification description providing unit.

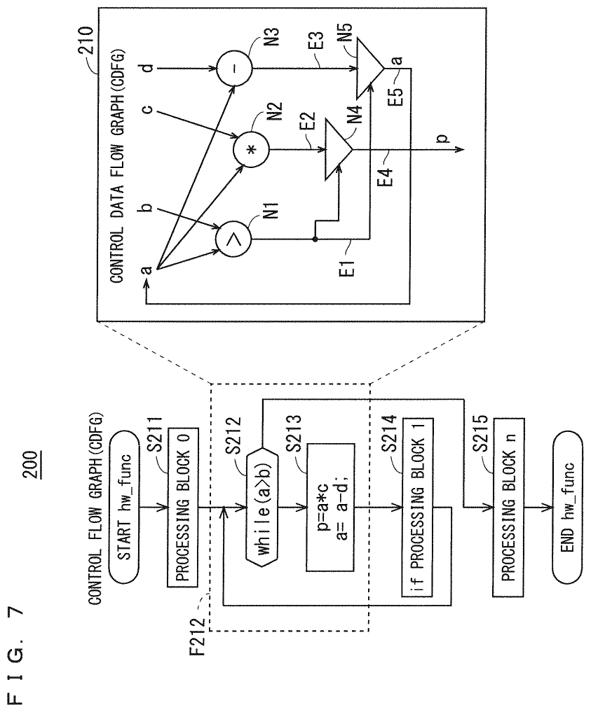

In step S1, the CDFG creation processing unit 21 in the high-level synthesis processing unit 2 creates the control data flow graph (CDFG) based on the behavioral description 11 in the specification descriptions 10. A specific example of the CDFG created by the CDFG creation processing unit 21 is shown in FIG. 7, which will be described below.

In step S2, the CDFG execution trace extension processing unit 22 in the high-level synthesis processing unit 2 performs execution trace extension processing of providing the execution trace extension function to the CDFG created by the CDFG creation processing unit 21 to acquire the CDFG with execution trace extension.

In step S3, the scheduling processing unit 23 in the high-level synthesis processing unit 2 performs the scheduling processing based on the high-level synthesis specification description 12 on the CDFG with execution trace extension generated by the CDFG execution trace extension processing unit 22 to acquire the scheduled CDFG.

In step S4, the binding processing unit 24 in the high-level synthesis processing unit 2 performs binding processing of allocating the hardware resource to the scheduled CDFG generated by the scheduling processing unit 23 to acquire the bound CDFG.

In step S5, the execution trace maximum window time calculation unit 25 in the high-level synthesis processing unit 2 calculates the maximum window time based on the bound CDFG generated by the binding processing unit 24. The maximum window time is maximum time to perform the trace processing without affecting behavioral processing performed by the information processing device implemented using the hardware descriptions 30.

In step S6, the state control machine generation unit 26 in the high-level synthesis processing unit 2 generates the state control machine indicating a plurality of transition states corresponding to the plurality of control states in the scheduled CDFG and transition between the plurality of transition states based on the scheduled CDFG generated by the scheduling processing unit 23. The state control machine thus substantially indicates transition between the plurality of control states.

In step S7, the execution trace mechanism generation unit 27 in the high-level synthesis processing unit 2 performs execution trace related information generation processing of generating the execution trace mechanism unit, the execution trace mechanism common unit, and the execution trace extension state control machine based on the execution trace specification description 13, the bound CDFG, the maximum window time, and the state control machine.

In step S8, the hardware description generation unit 28 in the high-level synthesis processing unit 2 generates the hardware descriptions 30 based on the bound CDFG, the execution trace mechanism unit, the execution trace mechanism common unit, and the execution trace extension state control machine.

### (Execution Trace Extension Processing)

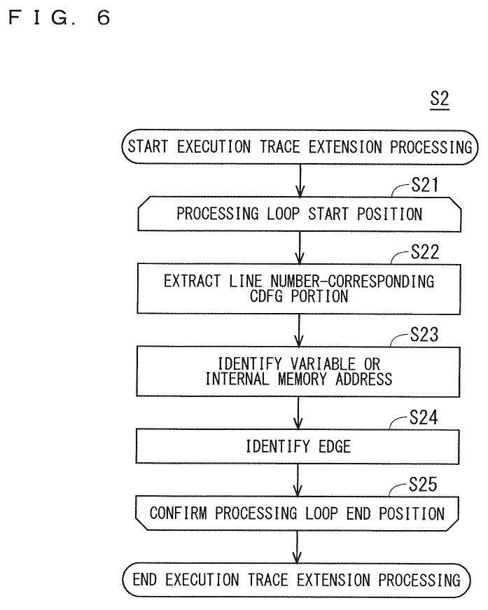

FIG. 6 is a flowchart showing processing procedures of the execution trace extension processing performed by the CDFG execution trace extension processing unit 22 in the high-level synthesis processing unit 2 in Embodiment 1 according to the present disclosure. That is to say, FIG. 6 shows details of content of processing performed in step S2 in FIG. 5.

After the CDFG is created by the CDFG creation processing unit 21, the CDFG execution trace extension processing unit 22 starts the execution trace extension processing.

Processing in steps S22 to S24 is repeated after a position of the start of a processing loop is specified in step S21 until a position of the end of the processing loop is confirmed in subsequent step S25.

The position of the start of the processing loop is the leading trace target line number indicated by the line number entry 130 in the execution trace specification description 13. The position of the start of the processing loop is the line number N1 in the execution trace specification description 13 shown in FIGS. 2 and 3.

On the other hand, the position of the end of the processing loop is the last trace target line number indicated by the line number entry 130 in the execution trace specification description 13. Thus, assuming that the last trace target line number is Nz in an example shown in FIGS. 2 and 3, the trace target line number is updated in the order of N1, N2, N3, N4, . . . , and Nz, and processing in steps S22 to S24 is performed.

In step S22, the CDFG execution trace extension processing unit 22 extracts a line number-corresponding CDFG portion from the CDFG created by the CDFG creation processing unit 21. The line number-corresponding CDFG portion refers to a portion of the CDFG corresponding to the trace target line number specified by the line number entry 130 in the execution trace specification description 13.

That is to say, step S22 is a step of extracting, from the CDFG, the portion corresponding to the trace target line number as the line number-corresponding CDFG portion.

In step S23, the CDFG execution trace extension processing unit 22 identifies, from the line number-corresponding CDFG portion extracted in step S22, a variable or an internal memory address corresponding to the recorded variable entry 132 in the execution trace specification description 13.

That is to say, step S23 is a step of identifying, from the line number-corresponding CDFG portion, the recorded variable indicated by the recorded variable entry 132 as the recorded variable information.

In step S24, the CDFG execution trace extension processing unit 22 identifies, from the line number-corresponding CDFG portion extracted in step S22, an edge of the CDFG where processing to the trace target line number is confirmed in the behavioral description 11.

That is to say, step S24 is a step of identifying the edge where the execution processing to the trace target line number is confirmed in the behavioral description 11.

In step S25, whether there is the position of the end of the processing loop is determined. Specifically, the CDFG execution trace extension processing unit 22 determines whether the trace target line number in the execution trace specification description 13 has ended in step S25.

That is to say, whether the trace target line number targeted for processing in steps S22 to S24 has reached the last trace target line number is determined in step S25. The last trace target line number is the position of the end of the processing loop.

In a case where the position of the end of the processing loop is not confirmed in step S25, the trace target line number is updated to the next trace target line number, and processing returns to step S22.

Processing in steps S22 to S24 for the updated trace target line number is repeated thereafter until the position of the end of the processing loop is confirmed in step S25.

The execution trace extension processing ends when the position of the end of the processing loop is confirmed in step S25.

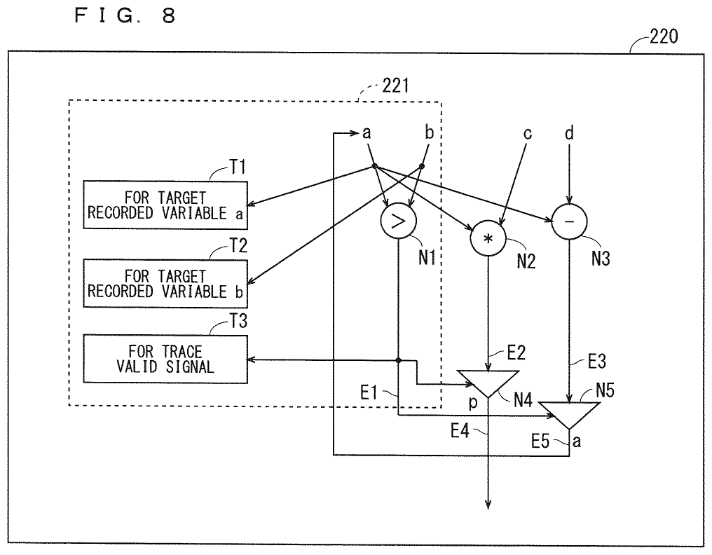

A specific example of the CDFG with execution trace extension created in the execution trace extension processing is shown in FIG. 8, which will be described below.

As described above, the CDFG execution trace extension processing performed by the CDFG execution trace extension processing unit 22 includes steps S21 to S25 described above, so that the CDFG with execution trace extension can be acquired from the CDFG.

### (CDFG: Control Data Flow Graph)

FIG. 7 is an illustration of a specific example of a CDFG 210 created by the CDFG creation processing unit 21 in Embodiment 1 according to the present disclosure.

The CDFG 210 creates, based on a control flow graph (hereinafter also abbreviated to “CFG”) 200 representing processing procedures of the behavioral description 11, the CDFG 210 obtained by adding data dependencies to the CFG 200.

While the CDFG creation processing unit 21 also creates the CFG as shown in FIG. 7, creation of the CFG itself is existing technology and has low relevance to features of Embodiment 1, so that details thereof are omitted.

An example shown in FIG. 7 shows the CFG 200 corresponding to a function hw_func corresponding to the behavioral description 11 shown in FIG. 4. An overview of the function hw_func will be described below.

In step S211, processing of a processing block 0 is performed. In step S212, true or not of a comparison operation (a>b) is determined. In a case where (a>b) is satisfied, processing in steps S213 and S214 is allowed under control performed in step S211. Step S214 shows an if processing block 1.

Step S215 shows an if processing block n executed after the end of processing in steps S212 to S214. Processing of the function hw_func ends when step S215 ends.

The CDFG 210 is created to correspond to an execution flow F212 including “while determination processing” in step S212 and “operation processing after while determination processing” in step S213 in the CFG 200.

In the CDFG 210, a node N1 indicates “magnitude comparison”, a node N2 indicates “multiplication”, a node N3 indicates “subtraction”, and a node N5 indicates a “selector” to output an edge signal E3 to be an input in a case where an edge signal E1 is true as it is as an edge signal E5. A node N4 indicates a “selector” to output an edge signal E2 as a result of multiplication at the node N2 in a case where the edge signal E1 is true as it is as an edge signal E4. These nodes N1 to N5 function as operation nodes.

As described above, the CDFG creation processing unit 21 generates, in addition to the CFG 200, the CDFG 210 based on the behavioral description 11.

(CDFG with Execution Trace Extension)

FIG. 8 is an illustration of a specific example of a CDFG with execution trace extension 220 created by the CDFG execution trace extension processing unit 22 in Embodiment 1 according to the present disclosure.

As shown in the figure, the CDFG with execution trace extension 220 is a graph obtained by extending the CDFG 210 with an execution trace extension portion 221. For example, in an example shown in FIG. 8, a graph to extend the CDFG 210 with a trace point T1, a trace point T2, and a trace point T3 based on the behavioral description 11 in an example shown in FIG. 4, the trace description DL12 shown in FIG. 4, and the CDFG 210 shown in FIG. 7 is the execution trace extension portion 221.

The trace point T1 is a trace point for a target recorded variable a and specifies a position of input of the variable a into the node N1. The trace point T2 is a trace point for a target recorded variable b and specifies a position of input of the variable b into the node N1. The trace point T3 is a trace point for a trace valid signal and specifies the edge signal E1 as an output signal from the node N1. The edge signal E1 is the trace valid signal.

For example, identification of an edge of the CDFG where execution processing to the behavioral description line CL1 shown in FIG. 4 is confirmed means that the edge signal E1 indicated by the trace point T3 is true in FIG. 8.

As described above, the CDFG execution trace extension processing unit 22 generates the CDFG with execution trace extension based on the execution trace specification description 13 and the CDFG.

### (Scheduled CDFG)

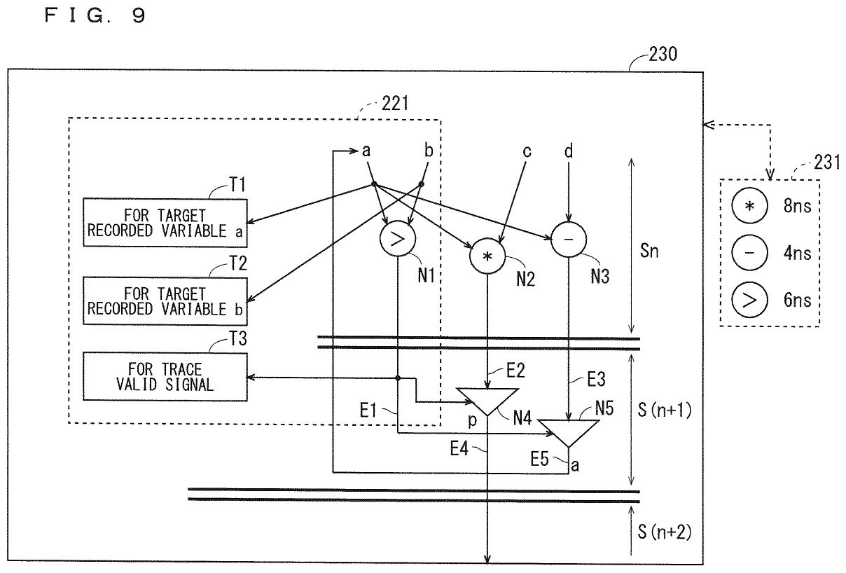

FIG. 9 is an illustration of a specific example of the scheduled CDFG created by the scheduling processing unit 23 in Embodiment 1 according to the present disclosure.

In an example shown in FIG. 9, an operation cycle at the node N1 for magnitude comparison is defined as 6 ns, an operation cycle at the node N2 for multiplication is defined as 8 ns, and an operation cycle at the node N3 for subtraction is defined as 6 ns based on operation time information 231 included in the high-level synthesis specification description 12.

The scheduled CDFG 230 is scheduled into step Sn including the nodes N1 to N3, step S(n+1) including the nodes N4 and N5, and step S(n+2) subsequent to step S(n+1) to satisfy the constraints on the clock period of 10 ns specified by the high-level synthesis specification description 12 shown in FIG. 4. Step Sn, step S(n+1), and step S(n+2) are the control states.

As described above, the scheduling processing unit 23 generates the scheduled CDFG based on the high-level synthesis specification description 12 and the CDFG with execution trace extension. The scheduled CDFG is divided into the plurality of control states.

### (Bound CDFG)

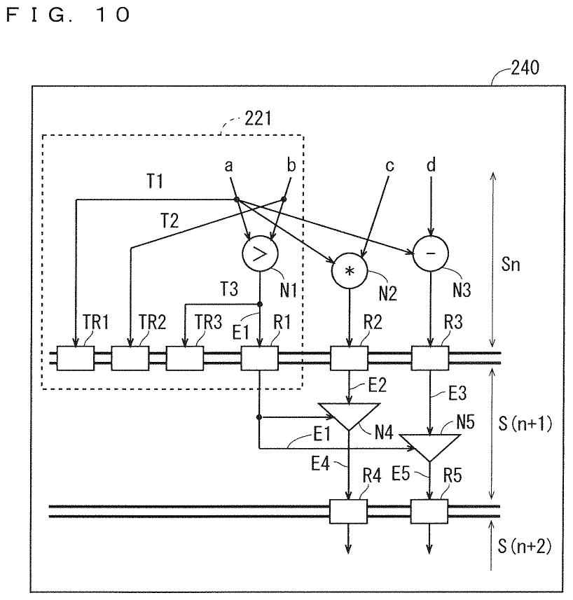

FIG. 10 is an illustration of a specific example of a bound CDFG 240 created by the binding processing unit 24 in Embodiment 1 according to the present disclosure. In an example shown in FIG. 10, CDFG registers R1 to R3 and trace registers TR1 to TR3 are allocated to a boundary between step Sn and step S(n+1). Furthermore, CDFG registers R4 and R5 are allocated to a boundary between step S(n+1) and step S(n+2). The CDFG registers R1 to R5 and the trace registers TR1 to TR3 are hardware resources.

The CDFG register R1 is provided for storage of the edge signal E1 from the node N1, the CDFG register R2 is provided for storage of the edge signal E2 from the node N2, and the CDFG register R3 is provided for storage of the edge signal E3 from the node N3. The CDFG register R4 is provided for storage of the edge signal E4 from the node N4, and the CDFG register R5 is provided for storage of the edge signal E5 from the node N5.

The trace register TR1 is provided for storage of the variable a specified by the trace point T1, the trace register TR2 is provided for storage of the variable b specified by the trace point T2, and the trace register TR3 is provided for storage of the edge signal E1 as the trace valid signal specified by the trace point T3.

In the example shown in FIG. 10, the hardware resources are all registers, and no memory is used.

As described above, the binding processing unit 24 performs the binding processing of allocating the hardware resource to the scheduled CDFG to acquire the bound CDFG.

### (Maximum Window Time Calculation Processing)

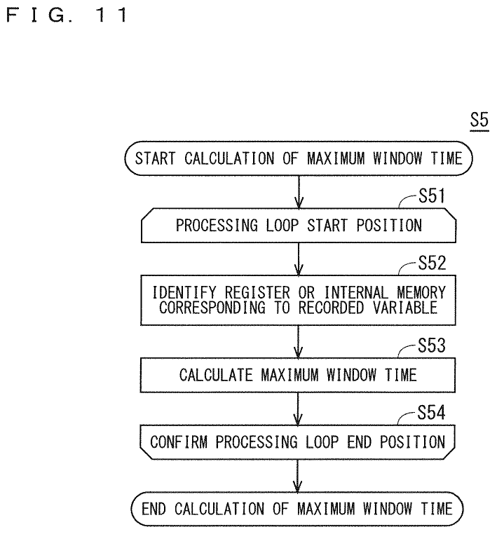

FIG. 11 is a flowchart showing processing procedures of maximum window time calculation processing performed by the execution trace maximum window time calculation unit 25 in Embodiment 1 according to the present disclosure. That is to say, FIG. 11 is a flowchart showing details of step S5 shown in FIG. 5.

After the bound CDFG is generated by the binding processing unit 24, the execution trace maximum window time calculation unit 25 starts the maximum window time calculation processing.

Processing in steps S52 and S53 is repeated after a position of the start of a processing loop is specified in step S51 until a position of the end of the processing loop is confirmed in subsequent step S54.

The position of the start of the processing loop in step S51 is the leading trace target line number indicated by the line number entry 130 in the execution trace specification description 13. On the other hand, the position of the end of the processing loop in step S54 is the last trace target line number indicated by the line number entry 130 in the execution trace specification description 13.

In step S52, the execution trace maximum window time calculation unit 25 identifies, from the bound CDFG, a register or an internal memory corresponding to the recorded variable entry 132.

That is to say, step S52 is a step of identifying, from the bound CDFG, a recorded variable storage corresponding to the recorded variable corresponding to the trace target line number in the execution trace specification description 13. For example, the trace registers TR1 and TR2 in FIG. 10 correspond to the recorded variable storage.

In step S53, the execution trace maximum window time calculation unit 25 calculates an update cycle of an update of the register or the internal memory identified in step S52 as the maximum window time.

That is to say, step S53 is a step of calculating, as the maximum window time, an update cycle of an update of stored content in the trace registers TR1 and TR2 as the recorded variable storage.

For example, if the trace time to perform the trace processing for the variable a exceeds the update cycle of the trace register TR1, content of the variable a is updated, and the trace processing cannot properly be performed. In this case, the information processing device implemented using the hardware descriptions 30 is required to be stopped to precisely perform the trace processing. As a result, the trace processing affects operation of the information processing device.

The maximum window time acquired in step S53 is thus the maximum time to perform the trace processing without affecting behavioral processing performed by the information processing device.

In step S54, whether there is the position of the end of the processing loop is determined. That is to say, whether the trace target line number targeted for processing has reached the last trace target line number is determined in step S54. The last trace target line number is the position of the end of the processing loop.

In a case where the position of the end of the processing loop is not confirmed in step S54, the trace target line number is updated to the next trace target line number, and processing returns to step S52.

Processing in steps S52 and SS3 for the updated trace target line number is repeated thereafter until the position of the end of the processing loop is confirmed in step S54.

The maximum window time calculation processing ends when the position of the end of the processing loop is confirmed in step S54.

As described above, the execution trace maximum window time calculation unit 25 performs the maximum window time calculation processing of calculating the maximum window time corresponding to the trace target line number on the bound CDFG.

The maximum window time calculation processing performed by the execution trace maximum window time calculation unit 25 in Embodiment 1 includes steps S51 to S54 described above, so that the maximum window time can be calculated from the bound CDFG.

### (State Control Machine)

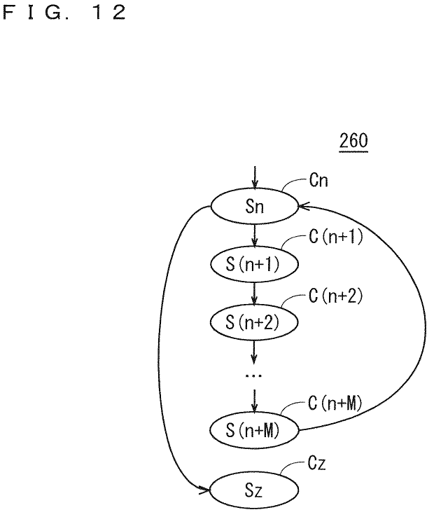

FIG. 12 is an illustration of a specific example of the state control machine generated by the state control machine generation unit 26 in Embodiment 1 according to the present disclosure. In an example shown in FIG. 12, a state Cn corresponding to step Sn, a state C(n+1) corresponding to step S(n+1), and a state C(n+2) corresponding to step S(n+2) are set from a “while block” in the behavioral description 11 shown in the example of FIG. 4 and the scheduled CDFG 230 shown in FIG. 9.

Furthermore, a state C(n+M) corresponding to step S(n+M) and a state Cz corresponding to step Sz are set. As described above, the plurality of transition states corresponding to the plurality of control states are set within a state control machine 260.

Steps Sn to Sz described above are the plurality of control states, and the states Cn to Cz are the plurality of transition states corresponding to the plurality of control states.

Assume herein that step Sn is a step of starting the while block, and step S(n+M) is a step of ending the while block in the behavioral description 11. In this case, transition is shown in the order from the state Cn to the state C(n+M), and transition to return from the state C(n+M) to the state Cn and transition to shift from the state Cn to the state Cz are provided. That is to say, transition between the state Cn and step S(n+M) is transition during continuation of the while block, and transition from the state Cn to the state Cz is transition at the end of the while block.

As described above, a graph showing the plurality of transition states corresponding to the plurality of control states divided from the scheduled CDFG and transition between the plurality of transition states is the state control machine 260. The plurality of control states and the plurality of transition states are equivalent to each other, and thus the state control machine 260 is substantially a graph showing transition between the plurality of control states.

### (Execution Trace Mechanism Generation Unit)

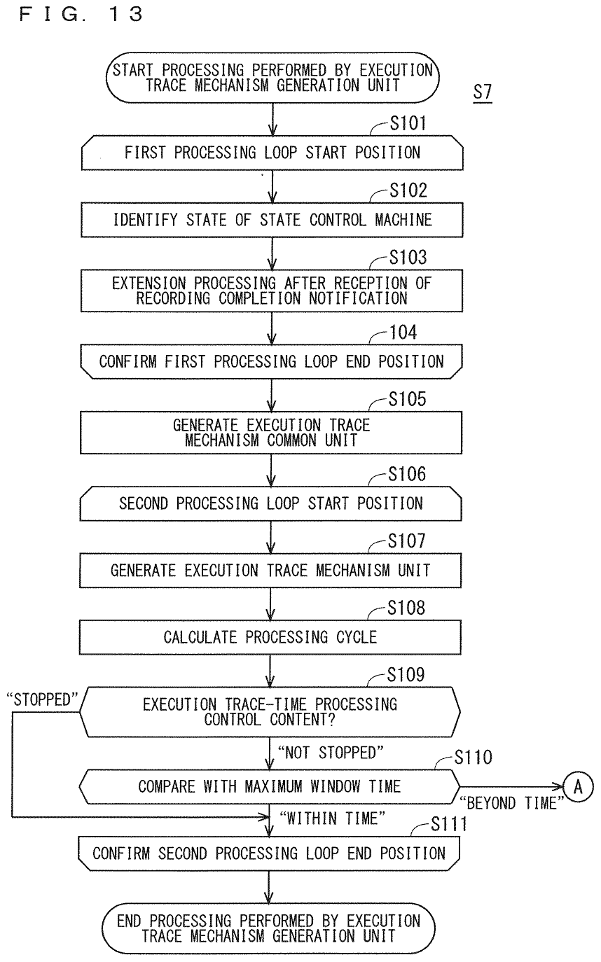

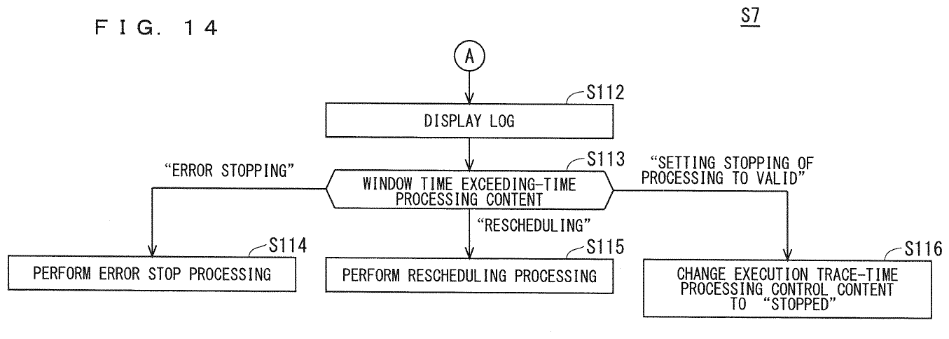

FIGS. 13 and 14 are a flowchart showing processing procedures of the execution trace related information generation processing performed by the execution trace mechanism generation unit 27 in Embodiment 1 according to the present disclosure. That is to say, FIGS. 13 and 14 are a flowchart showing details of step S7 shown in FIG. 5.

After the state control machine is generated by the state control machine generation unit 26, the execution trace mechanism generation unit 27 starts the execution trace related information generation processing.

Processing in steps S102 and S103 is repeated after a position of the start of a first processing loop is specified in step S101 until a position of the end of the first processing loop is confirmed in subsequent step S104.

The position of the start of the first processing loop in step S101 is the leading trace target line number indicated by the line number entry 130 in the execution trace specification description 13. On the other hand, the position of the end of the first processing loop in step S104 is the last trace target line number indicated by the line number entry 130 in the execution trace specification description 13.

In step S102, the execution trace mechanism generation unit 27 identifies a transition state of the state control machine in which the execution processing to the trace target line number is confirmed. The transition state corresponds to a control state in the scheduled CDFG.

In step S103, in a case where the execution trace-time processing control entry 135 specified by the execution trace specification description 13 indicates that processing is “STOPPED”, the execution trace mechanism generation unit 27 performs extension processing so that the state of the state control machine identified in step S102 transitions to a subsequent state after a recording completion signal for the trace information is received.

In step S104, whether there is the position of the end of the first processing loop is determined. That is to say, whether the trace target line number targeted for processing has reached the last trace target line number is determined in step S104. The last trace target line number is the position of the end of the processing loop.

In a case where the position of the end of the first processing loop is not confirmed in step S104, the trace target line number is updated to the next trace target line number, and processing returns to step S102.

Processing in steps S102 and S103 for the updated trace target line number is repeated thereafter until the position of the end of the first processing loop is confirmed in step S104.

When the position of the end of the first processing loop is confirmed in step S104, processing transitions to step S105.

Steps S101 to S104 described above are steps of identifying the state of the state control machine in which the execution processing to the trace target line number corresponding to the trace target line number in the execution trace specification description 13 is confirmed and performing the extension processing of the state control machine when recording is completed. The “state of the state control machine” exactly refers to a transition state, and the transition state corresponds to one of the plurality of control states divided from the scheduled CDFG.

In step S105, the execution trace mechanism generation unit 27 generates the execution trace mechanism common unit including a clock counter and a recording memory transfer unit as intermediate data.

Processing in steps S108 to S110 is repeated after a position of the start of a second processing loop is specified in step S106 until a position of the end of the second processing loop is confirmed in subsequent step S111.

The position of the start of the second processing loop in step S106 is the leading trace target line number indicated by the line number entry 130 in the execution trace specification description 13. On the other hand, the position of the end of the processing loop in step S111 is the last trace target line number indicated by the line number entry 130 in the execution trace specification description 13.

In step S107, the execution trace mechanism generation unit 27 generates the execution trace mechanism unit, which will be described below. The execution trace mechanism unit is a trace basic portion to perform the trace processing for each trace target line number.

In step S108, the execution trace mechanism generation unit 27 calculates a processing cycle of the execution trace mechanism unit generated in step S107.

As described above, steps S107 and S108 are steps of generating the execution trace mechanism unit corresponding to the trace target line number in the execution trace specification description 13 and calculating the processing cycle of the generated execution trace mechanism unit.

In a case where the execution trace-time processing control entry 135 in the execution trace specification description 13 indicates that processing is “NOT STOPPED” in step S109, the execution trace mechanism generation unit 27 proceeds to step S110. On the other hand, in a case where the execution trace-time processing control entry 135 indicates that processing is “STOPPED” in step S109, processing proceeds to step S111 without performing step S110.

In step S110, the execution trace mechanism generation unit 27 compares the processing cycle of an execution trace mechanism unit 1320 calculated in step S108 and the maximum window time calculated in step S53 shown in FIG. 11.

A result of comparison is “WITHIN TIME” in a case where the processing cycle is shorter than or equal to the maximum window time and is “BEYOND TIME” in a case where the processing cycle exceeds the maximum window time. In a case where the result of comparison in step S110 is “WITHIN TIME”, processing proceeds to step S111.

On the other hand, in a case where the result of comparison in step S110 is “BEYOND TIME”, processing proceeds to step S112. That is to say, processing is forcibly removed from the second processing loop in a case where the result of comparison in step S100 is “BEYOND TIME”.

In step S111, whether there is the position of the end of the second processing loop is determined. That is to say, whether the trace target line number targeted for processing has reached the last trace target line number is determined in step S111. The last trace target line number is the position of the end of the processing loop.

In a case where the position of the end of the processing loop is not confirmed in step S111, the trace target line number is updated to the next trace target line number, and processing returns to step S107.

Processing in steps S107 to S110 for the updated trace target line number is repeated thereafter until the position of the end of the second processing loop is confirmed in step S111 or it is determined that the result is “BEYOND TIME” in step S110.

The execution trace related information generation processing ends when the position of the end of the second processing loop is confirmed in step S111.

Generation exception processing including steps S112 to S116 performed in a case where the result is “BEYOND TIME” in step S110 will be described below with reference to FIG. 14. Processing including steps S101 to S111 described above is generation basic processing.

The generation exception processing is performed in a case where the execution trace-time processing control entry 135 in the execution trace specification description 13 indicates that processing is not stopped and the processing cycle obtained in step S108 exceeds the maximum window time.

In step S112, the execution trace mechanism generation unit 27 displays a log including entry information in the execution trace specification description 13, the maximum window time, and the processing cycle of the execution trace mechanism unit on a display device of the high-level synthesis device 100.

As the entry information in the execution trace specification description 13, a current trace target line number in the execution trace specification description 13 repeated in steps S106 to S111 is considered, for example. In this case, the execution trace specification description 13 corresponding to the entry information refers to content of the execution trace specification description 13 corresponding to the trace target line number.

A user terminal mounted on a system mounted on a personal computer and a workstation is considered as the display device. An unillustrated display device connected to the bus 96 in FIG. 23 is also considered as the display device. Furthermore, the high-level synthesis device 100 may hold processing log information of the high-level synthesis processing unit 2 as a log file. The log file may be stored in the memory 92 shown in FIG. 23, for example.

As described above, step S112 is a step of displaying the log at least including the trace target line number, the maximum window time, and the processing cycle on the display device.

In step S113, the execution trace mechanism generation unit 27 determines processing operation of the execution trace mechanism generation unit 27 specified by the recording window time exceeding-time entry in the high-level synthesis control entry 136 in the execution trace specification description 13.

Processing proceeds to step S114 in a case where “ERROR STOPPING” is specified as the processing operation in step S113, proceeds to step S115 in a case where “RESCHEDULING” is specified as the processing operation in step S113, and proceeds to step S116 in a case where “SETTING STOPPING OF EXECUTION TRACE-TIME PROCESSING TO VALID” is specified as the processing operation in step S113.

In step S114, the execution trace mechanism generation unit 27 performs error stopping of the execution trace mechanism generation unit 27 and the high-level synthesis processing unit 2. Content indicating that error stopping is performed may be displayed on the above-mentioned display device, for example.

In step S115, the execution trace mechanism generation unit 27 performs the rescheduling processing. We focus on the update cycle of the update of content in the register or the internal memory corresponding to the recorded variable entry 132 in a portion of the bound CDFG corresponding to the trace target line number based on the trace target line number as a current entry in the second processing loop. The rescheduling processing is processing of performing the scheduling processing in step S3 in FIG. 5 again under the constraints that the update cycle we focus on is changed to a cycle equal to or more than the processing cycle of the execution trace mechanism unit calculated in step S108.

In step S116, the execution trace mechanism generation unit 27 changes the execution trace-time processing control entry 135 so that it indicates that processing is “STOPPED” for the trace target line number as the current entry in the second processing loop. The execution trace related information generation processing is then started again. In starting the execution trace related information generation processing again, the execution trace related information generation processing may be started again with the current trace target line number as a start line number without repeating the execution trace related information generation processing for all the trace target line numbers in the execution trace specification description 13 in the first and second processing loops.

As described above, processing in steps S113 to S116 is a step of performing one of error stop processing, the rescheduling processing, and processing of changing content of the execution trace-time processing control entry 135 based on the high-level synthesis control entry 136 in the execution trace specification description 13.

The error stop processing includes stopping of the high-level synthesis processing, and the rescheduling processing is processing of generating the scheduled CDFG again as described above for the scheduling processing unit 23.

The execution trace mechanism generation unit 27 performs the generation basic processing including steps S101 to S111 of the execution trace related information generation processing to generate the execution trace mechanism unit and the execution trace mechanism common unit as the intermediate data.

The execution trace mechanism generation unit 27 performs the generation exception processing including steps S112 to S116 of the execution trace related information generation processing to appropriately take a measure that is exceptionally necessary.

### (Execution Trace Mechanism Unit Generation Processing)

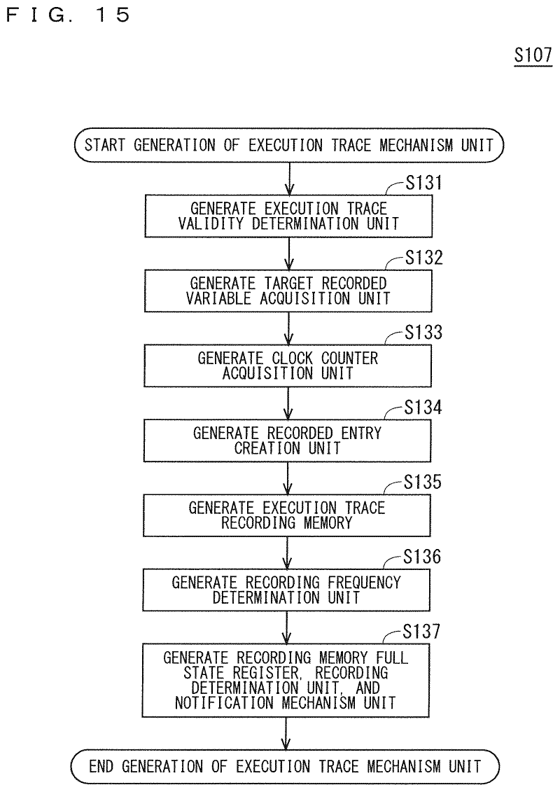

FIG. 15 is a flowchart showing processing procedures of execution trace mechanism unit generation processing performed by the execution trace mechanism generation unit 27 in Embodiment 1 according to the present disclosure. That is to say, FIG. 15 is a flowchart showing details of step S107 shown in FIG. 13.

After step S106 is performed, the execution trace mechanism unit generation processing is started in step S107.

In step S131, the execution trace mechanism generation unit 27 generates an execution trace validity determination unit based on an edge as the trace valid signal from among the edge identified in step S24 in FIG. 6 and the state of the state control machine identified in step S102 in FIG. 13 for the current trace target line number as the current entry in the execution trace specification description 13.

The edge signal E1 from the node N1 indicated by the trace point T3 in FIG. 10 corresponds to the trace valid signal, for example. The state control machine 260 shown in FIG. 12 corresponds to the identified state control machine, for example.

In step S132, the execution trace mechanism generation unit 27 generates a target recorded variable acquisition unit to acquire a recorded variable value from the register or the internal memory address corresponding to the recorded variable identified in step S52 in FIG. 11 for the current trace target line number in the execution trace specification description 13. The trace registers TR1 and TR2 shown in FIG. 10 are considered as the register corresponding to the recorded variable, for example.

In step S133, the execution trace mechanism generation unit 27 generates a clock counter acquisition unit to acquire a clock counter value from the clock counter in the execution trace mechanism common unit generated in step S105 in FIG. 13.

In step S134, the execution trace mechanism generation unit 27 generates a recorded entry creation unit to create the trace information as a recorded entry based on the trace target line number, the recorded variable specified by the recorded variable entry 132, and information specified by the clock counter information entry 133 for the current trace target line number in the execution trace specification description 13. The information specified by the clock counter information entry 133 is recorded or not recorded.

In step S135, the execution trace mechanism generation unit 27 generates an execution trace recording memory based on the number of memories and the memory size specified by the recording scheme entry 134 for the current trace target line number in the execution trace specification description 13.

In step S136, the execution trace mechanism generation unit 27 generates a recording frequency determination unit according to the frequency of recording specified by the recording scheme entry 134 for the current trace target line number in the execution trace specification description 13.

In step S137, the execution trace mechanism generation unit 27 generates a recording memory full state register indicating a state of the capacity of the recording memory, a recording determination unit to determine whether to perform recording, and a notification mechanism unit to provide notification of the memory full state of the execution trace recording memory and completion of recording on the execution trace recording memory.

The execution trace mechanism generation unit 27 then ends the execution trace mechanism unit generation processing. The generated execution trace mechanism unit is the trace basic portion to perform the trace processing for each trace target line number. The nine components generated in steps S131 to S137 are all intermediate data.

### (Execution Trace Mechanism Unit Description and Execution Trace Mechanism Common Unit Description)

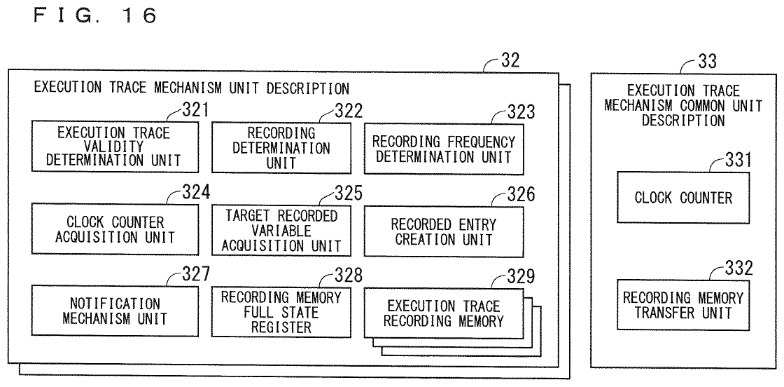

FIG. 16 is a block diagram showing configurations of the execution trace mechanism unit description 32 and the execution trace mechanism common unit description 33 generated by the hardware description generation unit 28 of the high-level synthesis device 100 in Embodiment 1 according to the present disclosure.

The execution trace mechanism unit description 32 is a HW description corresponding to the execution trace mechanism unit as the intermediate data generated in step S107 in FIG. 13. The hardware description generation unit 28 generates the execution trace mechanism unit description 32 based on the execution trace mechanism unit.

The execution trace mechanism common unit description 33 is a HW description corresponding to the execution trace mechanism common unit as the intermediate data generated in step S105 in FIG. 13. The hardware description generation unit 28 generates the execution trace mechanism common unit description 33 based on the execution trace mechanism common unit.

The execution trace mechanism unit description 32 at least includes an execution trace validity determination unit 321, a recording determination unit 322, a recording frequency determination unit 323, a clock counter acquisition unit 324, a target recorded variable acquisition unit 325, a recorded entry creation unit 326, a notification mechanism unit 327, a recording memory full state register 328, and an execution trace recording memory 329.

A portion of the information processing device 1000, which will be described below with reference to FIG. 17, can be formed by performing logic synthesis and place-and-route based on the execution trace mechanism unit description 32 and the execution trace mechanism common unit description 33.

The execution trace validity determination unit 321 is a HW description corresponding to the execution trace validity determination unit as the intermediate data generated in step S131 in FIG. 15 and is a HW description having a function to determine whether the execution trace mechanism unit is valid. That is to say, the execution trace validity determination unit 321 is a HW description to determine validity of the trace processing.

Similarly, the target recorded variable acquisition unit 325 is a HW description corresponding to the target recorded variable acquisition unit as the intermediate data generated in step S132 in FIG. 15. That is to say, the target recorded variable acquisition unit 325 is a HW description having a function to acquire the recorded variable value to be included in execution trace information.

The clock counter acquisition unit 324 is a HW description corresponding to the clock counter acquisition unit as the intermediate data generated in step S133 in FIG. 15. That is to say, the clock counter acquisition unit 324 is a HW description having a function to acquire the clock count value.

The recorded entry creation unit 326 is a HW description corresponding to the recorded entry creation unit as the intermediate data generated in step S134 in FIG. 15. That is to say, the recorded entry creation unit 326 is a HW description having a function to create the recorded entry of the execution trace information. The execution trace information includes the current trace target line number, the clock count value, and the recorded variable value.

The execution trace recording memory 329 is a HW description corresponding to the execution trace recording memory as the intermediate data generated in step S135 in FIG. 15. That is to say, the execution trace recording memory 329 is a HW description to record the execution trace information and satisfies content of the recording scheme entry 134 as the recording scheme information.

Furthermore, the recording frequency determination unit 323 is a HW description corresponding to the recording frequency determination unit 323 as the intermediate data generated in step S136 in FIG. 15. That is to say, the recording frequency determination unit 323 is a HW description having a function to determine the frequency of recording of the execution trace information.

The recording memory full state register 328, the recording determination unit 322, and the notification mechanism unit 327 are HW descriptions corresponding to the recording memory full state register, the recording determination unit, and the notification mechanism unit as a group of intermediate data generated in step S137 in FIG. 15.

The above-mentioned recording memory full state register 328 is a HW description for a register to hold information on the state of the capacity of the execution trace recording memory. The recording memory full state register 328 may be a memory to hold state information.

The above-mentioned recording determination unit 322 is a HW description having a function to determine whether recording can be performed.

The above-mentioned notification mechanism unit 327 is a HW description having a function to at least provide notification of the recording memory full state and completion of recording.

The execution trace mechanism common unit description 33 at least includes a clock counter 331 and a recording memory transfer unit 332.

The clock counter 331 has a function to count a clock as time information and is a HW description having a function to provide the clock count value.

The recording memory transfer unit 332 is a HW description having a function to transfer content held by the execution trace recording memory 329 to an information holding device as a data storage destination other than the execution trace recording memory 329. The external memory and the secondary storage device are considered as the information holding device.

The execution trace mechanism generation unit 27 generates the execution trace mechanism unit as shown in FIG. 15 to generate intermediate data corresponding to the HW descriptions 321 to 329 in the execution trace mechanism unit description 32 shown in FIG. 16.

The execution trace mechanism generation unit 27 generates the execution trace mechanism common unit as shown in step S105 in FIG. 13 to generate intermediate data corresponding to the HW descriptions 331 and 332 in the execution trace mechanism common unit description 33 shown in FIG. 16.

### (Effects)

The high-level synthesis processing unit 2 of the high-level synthesis device 100 according to the present disclosure generates, as a portion of the hardware descriptions 30, the execution trace mechanism unit description 32 and the execution trace mechanism common unit description 33 describing the execution trace function to perform the trace processing based on the behavioral description 11 and the execution trace specification description 13. The execution trace mechanism unit description 32 and the execution trace mechanism common unit description 33 are the execution trace hardware descriptions.

As shown in FIGS. 2 and 3, the various entries 131 to 137 are described to correspond to the trace target line number indicated by the line number entry 130 in the execution trace specification description 13. On the other hand, the unit behavior indicated by the behavioral description 11 is described to correspond to the line number. The execution trace specification description 13 is thus a specification description for the trace processing described to correspond to the unit behavior in the behavioral description 11.

The information processing device obtained by hardware implementation using the hardware descriptions 30 generated by the high-level synthesis device 100 in Embodiment 1 can thus have the execution trace function corresponding to the unit behavior in the behavioral description 11.

That is to say, the information processing device implemented using the hardware descriptions 30 can acquire and record information during hardware operation corresponding to the behavioral description 11.

The high-level synthesis processing unit 2 of the high-level synthesis device 100 includes the CDFG creation processing unit 21, the CDFG execution trace extension processing unit 22, the scheduling processing unit 23, and the binding processing unit 24.

The high-level synthesis processing unit 2 can thus acquire the bound CDFG based on the behavioral description 11, the high-level synthesis specification description 12, and the execution trace specification description 13.

The high-level synthesis processing unit 2 further includes the execution trace maximum window time calculation unit 25. The maximum time allowed for the trace processing can thus be calculated by the execution trace maximum window time calculation unit 25.

The high-level synthesis processing unit 2 includes the state control machine generation unit 26 and the execution trace mechanism generation unit 27. The execution trace mechanism unit, the execution trace mechanism common unit, and the execution trace extension state control machine as intermediate data can thus be generated by the execution trace mechanism generation unit 27.

The high-level synthesis processing unit 2 includes the hardware description generation unit 28. The hardware descriptions 30 used to implement the information processing device as the hardware circuit having the execution trace function can thus eventually be generated by the hardware description generation unit 28.

The high-level synthesis device 100 includes the hardware description storage 3. The hardware descriptions 30 including the behavioral processing hardware description 31, the execution trace mechanism unit description 32, and the execution trace mechanism common unit description 33 can thus be stored in the hardware description storage 3.

The behavioral processing hardware description 31 includes the execution trace extension hardware description 311 and the execution trace extension state control machine 312. A portion of the trace function can thus be incorporated into a logical function of the information processing device 1000.

The trace processing entry 131, the recorded variable entry 132, the clock counter information entry 133, the recording scheme entry 134, the execution trace-time processing control entry 135, and the high-level synthesis control entry 136 are included in the execution trace specification description 13 to correspond to the trace target line number indicated by the line number entry 130.

The high-level synthesis device 100 in Embodiment 1 can thus generate the hardware descriptions 30 for the information processing device 1000 having a sophisticated trace function based on the execution trace specification description 13 describing content of the trace processing in detail.

The execution trace specification description 13 further includes the pragma description entry 137 describing the pragma description. Content of the execution trace specification description 13 can thus relatively easily be recognized with reference to the pragma description indicated by the pragma description entry 137.

A modification in which content of the pragma description entry 137 is directly described in the behavioral description line CL1 and the behavioral description line CL2 in the behavioral description 11 shown in FIG. 4 is considered.

That is to say, the pragma description may be incorporated into a line in the behavioral description as the trace target line number as in the modification. In a case of the modification, the pragma description is required to precisely reflect content of the entries 131 to 136 corresponding to the trace target line number.

In a case where the above-mentioned modification is used, the high-level synthesis processing unit 2 can generate the hardware descriptions 30 including the behavioral processing hardware description 31, the execution trace mechanism unit description 32, and the execution trace mechanism common unit description 33 based on the behavioral description 11 including therein the execution trace specification description 13.

### (High-Level Synthesis Method)

The high-level synthesis device 100 in Embodiment 1 can be used to perform a high-level synthesis method described below. The high-level synthesis method includes the following steps (a) and (b):
(a) a step of providing the specification descriptions 10 including the behavioral description 11 indicating the functional logic from the specification description storage 1 to the high-level synthesis processing unit 2; and
(b) a step of performing the high-level synthesis processing of acquiring the hardware descriptions 30 based on the specification descriptions 10 using the high-level synthesis processing unit 2.

The hardware descriptions 30 include the behavioral processing hardware description 31 for the information processing device obtained by hardware implementation of the functional logic described in the behavioral description 11, and the specification descriptions 10 further include the execution trace specification description 13 for the trace processing described to correspond to the behavioral description 11 in the information processing device.

In the high-level synthesis processing in step (b), the execution trace mechanism unit description 32 and the execution trace mechanism common unit description 33 indicating the execution trace function to perform the trace processing are further generated at least based on the behavioral description 11 and the execution trace specification description 13. The execution trace mechanism unit description 32 and the execution trace mechanism common unit description 33 are the execution trace hardware descriptions.

That is to say, the hardware descriptions 30 include the execution trace mechanism unit description 32 and the execution trace mechanism common unit description 33.

In the high-level synthesis processing performed by the above-mentioned high-level synthesis method, the execution trace mechanism unit description 32 and the execution trace mechanism common unit description 33 describing the execution trace function to perform the trace processing are generated as a portion of the hardware descriptions 30 based on the behavioral description 11 and the execution trace specification description 13.

As shown in FIGS. 2 and 3, the execution trace specification description 13 is the specification description for the trace processing described to correspond to the unit behavior in the behavioral description 11.

The information processing device obtained by hardware implementation using the hardware descriptions 30 generated by the above-mentioned high-level synthesis method can thus have the execution trace function corresponding to the unit behavior in the behavioral description 11.

### (Information Processing Device)

FIG. 17 is a block showing a configuration of the information processing device 1000 implemented using the hardware descriptions 30. The hardware descriptions 30 are generated by the high-level synthesis device 100 in Embodiment 1 according to the present disclosure.

The information processing device 1000 is a collection of hardware circuits (hereinafter also abbreviated to “HW circuits”). That is to say, the information processing device 1000 at least includes a behavioral processing unit HW circuit 1031, an execution trace extension state control machine HW circuit 1034, an execution trace mechanism unit HW circuit 1032, and an execution trace mechanism common unit HW circuit 1033.

The behavioral processing unit HW circuit 1031 and the execution trace extension state control machine HW circuit 1034 are HW circuits corresponding to the behavioral processing hardware description 31.

The execution trace mechanism unit HW circuit 1032 is a HW circuit corresponding to the execution trace mechanism unit description 32. The execution trace mechanism common unit HW circuit 1033 is a HW circuit corresponding to the execution trace mechanism common unit description 33.

In FIG. 17, the behavioral processing unit HW circuit 1031 is shown as a HW circuit corresponding to the bound CDFG 240 shown in FIG. 10. In FIG. 17, nodes N10 to N50 are hardware portions (hereinafter also abbreviated to “HW portions”) corresponding to the nodes N1 to N5. CDFG registers R10 to R50 are HW portions corresponding to the CDFG registers R1 to R5. Trace registers TR10 to TR30 are HW portions corresponding to the trace registers TR1 to TR3. The trace registers TR10 and TR20 are recorded variable storage HW portions, and the trace register TR30 is a valid signal storage HW portion.

The behavioral processing unit HW circuit 1031 is a HW circuit corresponding to the execution trace extension hardware description 311. The behavioral processing unit HW circuit 1031 includes an execution trace extension portion 1221. A portion of the behavioral processing unit HW circuit 1031 excluding the execution trace extension portion 1221 is a HW portion having a basic function. The behavioral processing unit HW circuit 1031 corresponds to the execution trace extension hardware description 311 so that the execution trace extension portion 1221 can be added to the basic function.

The execution trace extension state control machine HW circuit 1034 includes a state control machine 1260, a state register 1262, and a recording completion signal determination unit 1263. The execution trace extension state control machine HW circuit 1034 is a HW circuit corresponding to the execution trace extension state control machine 312.

The state control machine 1260, the state register 1262, and the recording completion signal determination unit 1263 are HW portions included in the execution trace extension state control machine HW circuit 1034.

The execution trace mechanism unit HW circuit 1032 is the HW circuit corresponding to the execution trace mechanism unit description 32. HW portions 1321 to 1329 in the execution trace mechanism unit HW circuit 1032 are HW portions corresponding to the HW descriptions 321 to 329 included in the execution trace mechanism unit description 32.

An execution trace validity determination unit 1321 is a HW portion corresponding to the execution trace validity determination unit 321, a recording determination unit 1322 is a HW portion corresponding to the recording determination unit 322, and a recording frequency determination unit 1323 is a HW portion corresponding to the recording frequency determination unit 323.

A clock counter acquisition unit 1324 is a clock counter acquisition unit HW portion corresponding to the clock counter acquisition unit 324, a target recorded variable acquisition unit 1325 is a target recorded variable acquisition unit HW portion corresponding to the target recorded variable acquisition unit 325, and a recorded entry creation unit 1326 is a recorded entry creation unit HW portion corresponding to the recorded entry creation unit 326.

A notification mechanism unit 1327 is a HW portion corresponding to the notification mechanism unit 327, a recording memory full state register 1328 is a recording memory full state register HW portion corresponding to the recording memory full state register 328, and an execution trace recording memory 1329 is a HW portion corresponding to the execution trace recording memory 329.

The execution trace mechanism common unit HW circuit 1033 is the HW circuit corresponding to the execution trace mechanism common unit description 33. The execution trace mechanism common unit HW circuit 1033 includes a clock counter 1331 and a recording memory transfer unit 1332.

The clock counter 1331 is a HW portion corresponding to the clock counter 331 included in the execution trace mechanism common unit description 33, and the recording memory transfer unit 1332 is a HW portion corresponding to the recording memory transfer unit 332 included in the execution trace mechanism common unit description 33.

As described above, the information processing device 1000 is a collection of the HW circuits generated by performing logic synthesis and place-and-route from the hardware descriptions 30 generated by the high-level synthesis processing performed by the high-level synthesis processing unit 2 of the high-level synthesis device 100. The information processing device 1000 can have the execution trace function corresponding to the behavioral description 11.

The execution trace mechanism unit HW circuit 1032 of the information processing device 1000 includes the HW portions 1321 to 1329 to form the trace basic portion to perform the trace processing in the execution trace function.

### (Trace Processing Performed by Information Processing Device)

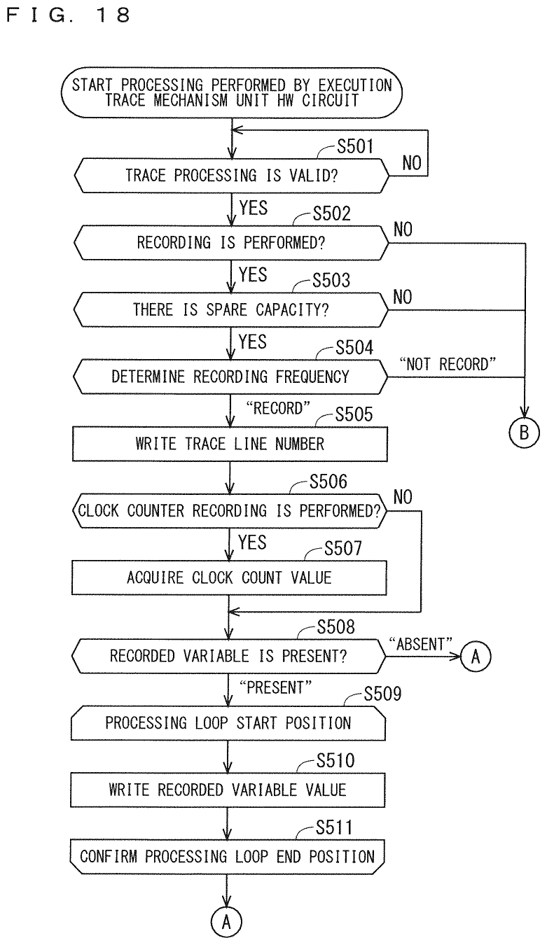

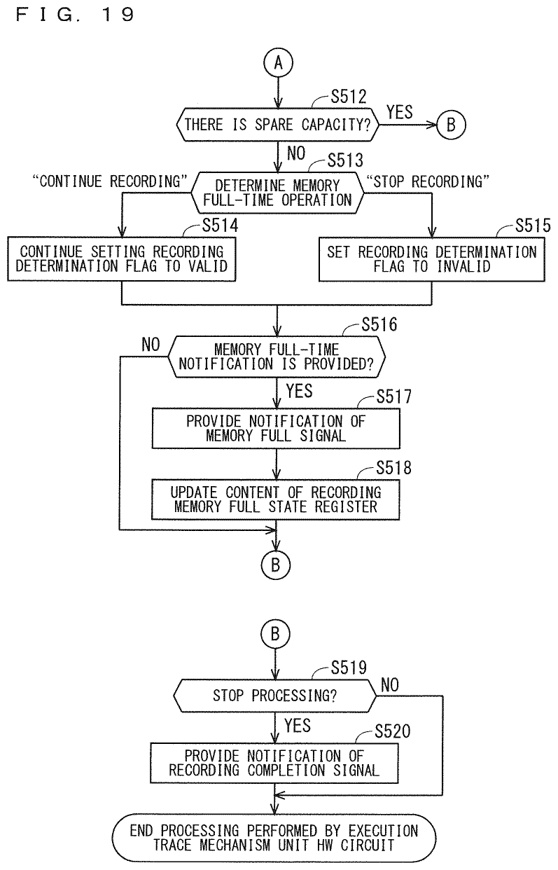

FIGS. 18 and 19 are a flowchart showing processing procedures of the trace processing performed by the execution trace mechanism unit HW circuit 1032 of the information processing device 1000. The trace processing includes trace basic processing and trace exception processing.

The execution trace mechanism unit HW circuit 1032 is started upon powering up of the information processing device 1000, for example.

In step S501, the execution trace validity determination unit 1321 in the execution trace mechanism unit HW circuit 1032 waits until the execution trace mechanism unit HW circuit 1032 is set to valid. That is to say, the execution trace validity determination unit 1321 determines validity of the trace processing.

Processing proceeds to step S502 in a case where the execution trace validity determination unit 1321 determines that the execution trace mechanism unit HW circuit 1032 is valid or has been set to valid. On the other hand, in a case where the execution trace validity determination unit 1321 determines that the execution trace mechanism unit HW circuit 1032 is not valid, the execution trace validity determination unit 1321 continues waiting until it is determined that the execution trace mechanism unit HW circuit 1032 is valid in step S501.

As described above, step S501 is a step of making execution trace validity determination using the execution trace validity determination unit 1321 as an execution trace validity determination unit HW portion.

As will be described below, the state information is transferred from the state register 1262 to the execution trace validity determination unit 1321 via a data path DP4. The state information indicates a state in the state control machine 1260. A stored value is transferred from the trace register TR30 to the execution trace validity determination unit 1321 via a data path DP3.

Consider a case where the execution trace mechanism unit HW circuit 1032 is set to valid during execution of the behavioral description line CL1 shown in FIG. 4, for example. In this case, the execution trace validity determination unit 1321 can determine that the execution trace mechanism unit HW circuit 1032 is valid in a case where the stored value in the trace register TR30 is received as the trace valid signal, the trace valid signal indicates true, that is, the trace valid signal indicates that an inequality “a>b” is satisfied, and the state information received from the state register 1262 via the data path DP4 indicates a signal receive control state. The “signal receive control state” refers to a control state in which the trace register TR30 is updated and the stored value therein can be received as the signal via the data path DP3. In an example shown in FIG. 17, a case where the control state is step S(n+1) corresponds to this case.

As described above, the execution trace validity determination unit 1321 can determine validity of the trace processing.

In step S502, the recording determination unit 1322 in the execution trace mechanism unit HW circuit 1032 determines whether a recording determination flag permits recording on the execution trace recording memory 1329. In a case where the recording determination flag permits recording (YES), processing proceeds to step S503. In a case where the recording determination flag prohibits recording (NO), processing proceeds to step S519. A register, a memory, and the like to hold information in the execution trace mechanism unit HW circuit 1032 or the recording determination unit 1322 are considered as the recording determination flag, for example.

As described above, step S502 is a step of determining whether to perform recording on the execution trace recording memory 1329 as an execution trace recording memory HW portion using the recording determination unit 1322 as a recording determination unit HW portion.

In step S503, the recording determination unit 1322 in the execution trace mechanism unit HW circuit 1032 determines whether there is spare capacity equal to or greater than written capacity in the execution trace recording memory 1329 in a subsequent step. Processing proceeds to step S504 in a case where the recording determination unit 1322 determines that there is the spare capacity in the execution trace recording memory 1329 and proceeds to step S519 in a case where the recording determination unit 1322 determines that there is no spare capacity in the execution trace recording memory 1329.

In step S504, the recording frequency determination unit 1323 in the execution trace mechanism unit HW circuit 1032 determines whether to record the trace information from recording frequency history. Processing proceeds to step S505 in a case where the recording frequency determination unit 1323 determines that recording is performed and proceeds to step S519 in a case where the recording frequency determination unit 1323 determines that recording is not performed.

The recording frequency history may be calculated from a recording-time counter value counting the number of times it is determined that recording is performed in step S504 and a non-recording counter value counting the number of times it is determined that recording is not performed in step S504. In a case where the frequency of recording described in the recording scheme entry 134 indicates 1/10, for example, the recording frequency history can be calculated based on a ratio of the recording-time counter value to the non-recording counter value.

As described above, step S504 is a step of determining whether to perform recording on the execution trace recording memory 1329 based on the recording frequency history using the recording frequency determination unit 1323 as a recording frequency determination unit HW portion.

In step S505, the recorded entry creation unit 1326 in the execution trace mechanism unit HW circuit 1032 writes the trace target line number as the current entry in the execution trace specification description 13 into the execution trace recording memory 1329.

As described above, step S505 is a step of writing the trace target line number in the execution trace specification description 13 into the execution trace recording memory 1329 using the recorded entry creation unit 1326.

In step S506, the recorded entry creation unit 1326 in the execution trace mechanism unit HW circuit 1032 determines whether to acquire the clock count value. Processing proceeds to step S507 in a case where the recorded entry creation unit 1326 determines that the clock count value is acquired and proceeds to step S508 in a case where the recorded entry creation unit 1326 determines that the clock count value is not acquired.

In step S507, the clock counter acquisition unit 1324 in the execution trace mechanism unit HW circuit 1032 acquires the clock count value from the clock counter 1331 via a data path DP7, which will be described below. The acquired clock count value is written into the execution trace recording memory 1329 by the recorded entry creation unit 1326.

As described above, steps S506 and S507 are steps of acquiring the clock count value from the clock counter 1331 as a clock counter HW portion and writing the acquired clock count value into the execution trace recording memory 1329 in a case where the clock count value is recorded.

In step S508, the execution trace mechanism unit HW circuit 1032 determines whether the recorded variable is present. Processing proceeds to step S509 in a case where the execution trace mechanism unit HW circuit 1032 determines that the recorded variable is present and proceeds to step S512 in a case where the execution trace mechanism unit HW circuit 1032 determines that he recorded variable is absent.

Processing in step S510 is repeated after a position of the start of a processing loop is specified in step S509 until a position of the end of the processing loop is confirmed in subsequent step S511.

The position of the start of the processing loop in step S509 is the leading recorded variable corresponding to the trace target line number indicated by the recorded variable entry 132 in the execution trace specification description 13. On the other hand, the position of the end of the processing loop in step S511 is the last recorded variable corresponding to the trace target line number indicated by the recorded variable entry 132.

In step S510, the target recorded variable acquisition unit 1325 in the execution trace mechanism unit HW circuit 1032 acquires the recorded variable value. The included recorded variable value is written into the execution trace recording memory 1329 by the recorded entry creation unit 1326.

In step S511, whether there is the position of the end of the processing loop is determined. That is to say, whether the recorded variable targeted for processing has reached the last recorded variable is determined in step S511. The last recorded variable is the position of the end of the processing loop.

In a case where the position of the end of the processing loop is not confirmed in step S511, the recorded variable is updated to the next recorded variable, and processing returns to step S510.

Processing in step S510 for the updated recorded variable is repeated thereafter until the position of the end of the processing loop is confirmed in step S511.

Processing proceeds to step S512 when the position of the end of the processing loop is confirmed in step S511.

As described above, steps S509 to S511 are steps of writing all the recorded variable values into the execution trace recording memory 1329 in a case where there is the recorded variable.

Processing in steps S501 to S511 shown in FIG. 18 is included in the trace basic processing. The trace exception processing in steps S512 to S520 will be described below with reference to FIG. 19.

In step S512, the recording determination unit 1322 in the execution trace mechanism unit HW circuit 1032 determines whether there is spare capacity equal to or greater than written capacity in the execution trace recording memory 1329 as in step S503. Processing proceeds to step S519 in a case where the recording determination unit 1322 determines that there is the spare capacity in the execution trace recording memory 1329 and proceeds to step S513 in a case where the recording determination unit 1322 determines that there is no spare capacity in the execution trace recording memory 1329.

In step S513, the execution trace mechanism unit HW circuit 1032 determines operation in a case where there is no spare capacity in the execution trace recording memory 1329, that is, the memory full-time operation. Processing proceeds to step S514 in a case where the memory full-time operation is “CONTINUE RECORDING” and proceeds to step S515 in a case where the memory full-time operation is “STOP RECORDING”. Content of determination of the memory full-time operation is indicated by the recording scheme entry 134.

In step S514, the execution trace mechanism unit HW circuit 1032 continues setting the recording determination flag to “VALID” to permit recording.

Steps S513 and S514 are steps of continuing setting the recording determination flag used by the recording determination unit 1322 to valid in a case where recording is continued when the execution trace recording memory 1329 is in the memory full state.

In step S515, the execution trace mechanism unit HW circuit 1032 sets the recording determination flag to “INVALID” to prohibit recording.

Steps S513 and S515 are steps of setting the recording determination flag to invalid in a case where recording is stopped when the execution trace recording memory 1329 is in the memory full state.

In step S516, the execution trace mechanism unit HW circuit 1032 determines whether to provide notification of the memory full state. Notification of the memory full state refers to notification indicating that there is no spare capacity in the execution trace recording memory 1329. Processing proceeds to step S517 in a case where the execution trace mechanism unit HW circuit 1032 determines that notification is provided in step S516 and proceeds to step S519 in a case where the execution trace mechanism unit HW circuit 1032 determines that notification is not provided in step S516.

In step S517, the notification mechanism unit 1327 in the execution trace mechanism unit HW circuit 1032 provides notification of the memory full signal including memory state information indicating that the execution trace recording memory 1329 is in the memory full state and secondary storage information specifying the data storage destination secondarily storing data in the execution trace recording memory 1329.

Steps S516 and S517 are steps of outputting the memory full signal at least including the memory state information indicating the memory full state from the notification mechanism unit 1327 as a notification mechanism unit HW portion in a case where notification is provided when the execution trace recording memory 1329 is in the memory full state.

In step S518, the execution trace mechanism unit HW circuit 1032 updates content of the recording memory full state register 1328 to a value indicating the full state.

In step S519, the execution trace mechanism unit HW circuit 1032 determines whether the behavioral processing unit HW circuit 1031 stops processing when the execution trace mechanism unit HW circuit 1032 performs the trace processing.

Processing proceeds to step S520 in a case where the execution trace mechanism unit HW circuit 1032 determines that processing is stopped in step S519, and processing performed by the execution trace mechanism unit HW circuit 1032 ends in a case where the execution trace mechanism unit HW circuit 1032 determines that processing is not stopped in step S519. Whether operation of the behavioral processing unit HW circuit 1031 is stopped is specified by the execution trace-time processing control entry 135 in the execution trace specification description 13.

In step S520, the notification mechanism unit 1327 in the execution trace mechanism unit HW circuit 1032 provides notification of the recording completion signal indicating completion of recording.

As described above, steps S519 and S520 are steps of outputting the recording completion signal indicating completion of recording from the notification mechanism unit 1327 as the notification mechanism unit HW portion in a case where the behavioral processing unit HW circuit 1031 stops processing.

Processing in steps S512 to S520 shown in FIG. 19 is included in the trace exception processing.

When processing ends, the execution trace mechanism unit HW circuit 1032 immediately returns to step S501 and waits until the execution trace mechanism unit HW circuit 1032 is set to valid again.

As described above, the information processing device 1000 can perform the trace processing including the trace basic processing including steps S501 to S511 in FIG. 18 and the trace exception processing including steps S512 to S520 in FIG. 19 using the execution trace mechanism unit HW circuit 1032.

### (Data Transfer Processing)

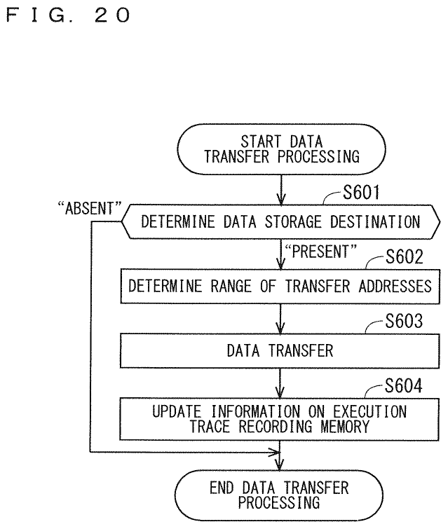

FIG. 20 is a flowchart indicating content of data transfer processing performed by the recording memory transfer unit 1332 in the execution trace mechanism common unit HW circuit 1033 in the information processing device 1000.

When notification of the memory full signal indicating that the execution trace recording memory 1329 is in the memory full state is provided from the notification mechanism unit 1327 in the execution trace mechanism unit HW circuit 1032 in step S517, that is, when the memory state information of the memory full signal indicates the memory full state, the recording memory transfer unit 1332 starts the data transfer processing with notification of the memory full signal as a trigger.

In step S601, the recording memory transfer unit 1332 determines whether the information holding device as the data storage destination to which data stored in the execution trace recording memory 1329 is transferred is present from the secondary storage information included in the memory full signal whose notification is provided in step S517. The external memory and the secondary storage device are considered as the information holding device.

Processing proceeds to step S602 in a case where the recording memory transfer unit 1332 determines that the data storage destination is “PRESENT”, and the data transfer processing ends in a case where the recording memory transfer unit 1332 determines that the data storage destination is “ABSENT”.

In step S602, the recording memory transfer unit 1332 determines a range of transfer addresses to which the data stored in the execution trace recording memory 1329 are transferred. The range of transfer addresses is a range of addresses in which untransferred data is stored in the execution trace recording memory 1329.

In step S603, the recording memory transfer unit 1332 transfers the untransferred data in the range of addresses determined in step S602 from the execution trace recording memory 1329 to the external information holding device.

As described above, steps S602 and S603 are steps of transferring, from among the data stored in the execution trace recording memory 1329, the untransferred data to the external data storage destination.

In step S604, the recording memory transfer unit 1332 updates information on the execution trace recording memory 1329. That is to say, the information is updated so that the range of addresses to which the data is transferred in step S603 is updated to a new spare region. In a case where the execution trace recording memory 1329 is of the ring type, the information can be updated using a memory management algorithm for a typical ring type, for example.

As described above, step S604 is a step of updating the information on the spare capacity in the execution trace recording memory 1329. After step S604 is performed, the recording memory transfer unit 1332 ends the data transfer processing.

The recording memory transfer unit 1332 as a recording memory transfer unit HW portion performs the above-mentioned data transfer processing to secure the spare capacity in the execution trace recording memory 1329 in a case where the execution trace recording memory 1329 is in the memory full state.

### (Data Path)

As described above, the behavioral processing unit HW circuit 1031 includes the trace registers TR10 and TR20 as the recorded variable storage HW portions corresponding to the trace registers TR1 and TR2 and includes the trace register TR30 as the valid signal storage HW portion corresponding to the trace register TR3.

The information processing device 1000 includes a data path DP1 provided between the trace register TR10 and the target recorded variable acquisition unit 1325 in the execution trace mechanism unit HW circuit 1032 and a data path DP2 provided between the trace register TR20 and the target recorded variable acquisition unit 1325 in the execution trace mechanism unit HW circuit 1032. The data paths DP1 and DP2 are first type data paths for data transfer of recorded variable values stored in the trace registers TR10 and TR20.

That is to say, the recorded variable values stored in the trace registers TR10 and TR20 are transferred to the target recorded variable acquisition unit 1325 via the data paths DP1 and DP2. The target recorded variable acquisition unit 1325 can thus acquire the recorded variable values.

The information processing device 1000 further includes the data path DP3 provided between the trace register TR3 and the execution trace validity determination unit 1321 in the execution trace mechanism unit HW circuit 1032. The data path DP3 is a second type data path for data transfer of the trace valid signal stored in the trace register TR3.

That is to say, the trace valid signal stored in the trace register TR3 is transferred to the execution trace validity determination unit 1321 via the data path DP3. The execution trace validity determination unit 1321 can thus determine validity of the trace processing based on the trace valid signal.

The information processing device 1000 can form a HW portion as a portion of the execution trace function using the execution trace validity determination unit 1321, the target recorded variable acquisition unit 1325, the trace registers TR10 and TR20, the trace register TR30, and the data paths DP1 to DP3.

As described above, the execution trace extension state control machine HW circuit 1034 includes the state control machine 1260, the state register 1262, and the recording completion signal determination unit 1263.

The state control machine 1260 is a state control machine HW portion corresponding to the state control machine generated by the state control machine generation unit 26.

The state register 1262 is a register to store the state information indicating transition of the state in the state control machine 1260.

The recording completion signal determination unit 1263 is a recording completion signal determination unit HW portion to determine completion of recording in the trace processing based on the recording completion signal acquired from the notification mechanism unit 1327.

The information processing device 1000 includes the data path DP4 provided between the state register 1262 and the execution trace validity determination unit 1321 in the execution trace mechanism unit HW circuit 1032. The data path DP4 is a third type data path for data transfer of the state information stored in the state register 1262.

That is to say, the state information is transferred from the state register 1262 to the execution trace validity determination unit 1321 via the data path DP4. The execution trace validity determination unit 1321 can thus recognize content of the transition of the state in the state control machine 1260 based on the state information.

The information processing device 1000 further includes a data path DP5 provided between the recording completion signal determination unit 1263 and the notification mechanism unit 1327 in the execution trace mechanism unit HW circuit 1032. The data path DP5 is a fourth type data path for data transfer of the recording completion signal.

That is to say, notification of the recording completion signal is provided from the notification mechanism unit 1327 to the recording completion signal determination unit 1263 via the data path DP5. The recording completion signal determination unit 1263 can thus recognize whether recording is completed based on the recording completion signal.

The information processing device 1000 can form a HW portion as a portion of the execution trace function using the state register 1262, the recording completion signal determination unit 1263, the execution trace validity determination unit 1321, the notification mechanism unit 1327, and the data paths DP4 and DP5 described above.

The high-level synthesis device 100 further includes a data path DP6 provided between the notification mechanism unit 1327 and the recording memory transfer unit 1332. The data path DP6 is a fifth type data path for data transfer of the memory full signal output from the notification mechanism unit 1327.

That is to say, notification of the memory full signal including the memory state information is provided from the notification mechanism unit 1327 to the recording memory transfer unit 1332 via the data path DP6. The recording memory transfer unit 1332 can thus start operation when the memory full signal indicates the memory full state.

The high-level synthesis device 100 further includes a data path DP7 provided between the clock counter 1331 and the clock counter acquisition unit 1324. The data path DP7 functions as a sixth type data path for data transfer of the clock count value.

That is to say, the clock count value can be transferred from the clock counter 1331 to the clock counter acquisition unit 1324 via the data path DP7. The clock counter acquisition unit 1324 can thus acquire the clock count value.

The information processing device 1000 can form a HW portion as a portion of the execution trace function using the clock counter acquisition unit 1324, the notification mechanism unit 1327, the clock counter 1331, the recording memory transfer unit 1332, and the data paths DP5 to DP7.

### Embodiment 2

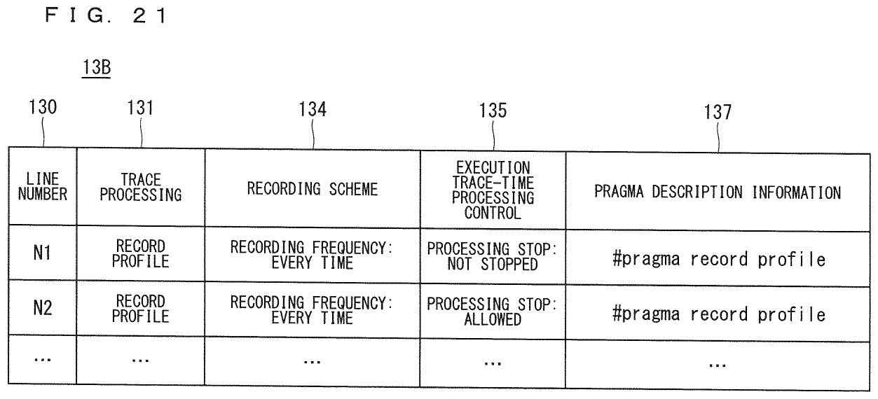

FIG. 21 is an illustration of an example of content of an execution trace specification description 13B in a high-level synthesis device 100B in Embodiment 2 according to the present disclosure shown in tabular form. The execution trace specification description 13B is assumed to be described so that the behavioral step to be the unit behavior indicated by the behavioral description 11 corresponds to the line number as in Embodiment 1.

The high-level synthesis device 100B in Embodiment 2 has a similar configuration to the high-level synthesis device 100 in Embodiment 1 shown in FIG. 1 except that the execution trace specification description 13 is replaced with the execution trace specification description 13B.

The execution trace specification description 13B in Embodiment 2 is different from the execution trace specification description 13 in Embodiment 1 shown in FIGS. 2 and 3 in that the recorded variable entry 132, the clock counter information entry 133, and the high-level synthesis control entry 136 are omitted.

That is to say, the execution trace specification description 13B includes only the line number entry 130, the trace processing entry 131, the recording scheme entry 134, the execution trace-time processing control entry 135, and the pragma description entry 137, and, further, an execution profile specification description is used in the trace processing entry 131.

The execution trace specification description 13B does not include the recorded variable entry 132, so that the maximum window time calculation processing corresponding to step S5 in FIG. 5 and shown in detail in FIG. 11 is omitted. In addition, processing of making comparison with the maximum window time in step S110 shown in FIG. 13 is omitted. Processing in steps S108 and S109 is also omitted. That is to say, after step S107 is performed, processing immediately proceeds to step S111.

The execution trace specification description 13B does not include the clock counter information entry 133 as the clock counter specifying information and thus may be considered to be equivalent to the clock count value not being recorded.

The recording scheme entry 134 in the execution trace specification description 13B only sets the frequency of recording to valid. The execution trace recording memory 1329 may be a static region to record, as a recording count value, information obtained by counting the number of executions by the trace target line number in the execution trace specification description 13B.

As for processing performed by the execution trace mechanism unit HW circuit 1032 shown in FIG. 18, it may always be determined that there is recording memory capacity in steps S503 and S512. Furthermore, in step S505, content of the recording count value may be updated to be counted up to correspond to the trace target line number.

As described above, the high-level synthesis device 100B in Embodiment 2 can generate the hardware descriptions for the information processing device having the trace function corresponding to the behavioral description 11 based on the execution trace specification description 13B including the minimum amount of information.

While the present disclosure has been described in detail, the foregoing description is in all aspects illustrative and not restrictive. It is understood that numerous unillustrated modifications can be devised without departing from the scope of the present disclosure.

Embodiments can thus freely be combined with each other, and can be modified or omitted as appropriate within the scope of the present disclosure.

### EXPLANATION OF REFERENCE SIGNS

1 specification description storage, 2 high-level synthesis processing unit, 3 hardware description storage, 10 specification descriptions, 11 behavioral description, 12 high-level synthesis specification description, 13, 13B execution trace specification description, 21 CDFG creation processing unit, 22 CDFG execution trace extension processing unit, 23 scheduling processing unit, 24 binding processing unit, 25 execution trace maximum window time calculation unit, 26 state control machine generation unit, 27 execution trace mechanism generation unit, 28 hardware description generation unit, 30 hardware descriptions, 31 behavioral processing hardware description, 32 execution trace mechanism unit description, 33 execution trace mechanism common unit description, 100, 100B high-level synthesis device, 311 execution trace extension hardware description, 312 execution trace extension state control machine, 1000 information processing device.

1. A high-level synthesis device comprising:
a specification description provider to provide specification descriptions including a behavioral description indicating functional logic; and
a high-level synthesis processor to perform high-level synthesis processing of generating hardware descriptions based on the specification descriptions, the hardware descriptions including a behavioral processing hardware description for an information processing device obtained by hardware implementation of the functional logic indicated by the behavioral description, wherein
the specification descriptions further include an execution trace specification description for trace processing described to correspond to the behavioral description,
in the high-level synthesis processing, an execution trace hardware description describing an execution trace function to perform the trace processing is further generated based on the behavioral description and the execution trace specification description,
the hardware descriptions include the execution trace hardware description,
the specification descriptions further include a high-level synthesis specification description defining high-level synthesis constraints,
the high-level synthesis processor includes:
a control data flow graph (CDFG) creation processor to create a CDFG based on the behavioral description;
a CDFG execution trace extension processor to provide an execution trace extension function to the CDFG based on the execution trace specification description to acquire a CDFG with execution trace extension;
a scheduling processor to perform scheduling processing based on the high-level synthesis specification description on the CDFG with execution trace extension to acquire a scheduled CDFG;
a binding processor to allocate a hardware resource to the scheduled CDFG to acquire a bound CDFG; and
an execution trace maximum window time calculator to calculate maximum window time based on the bound CDFG,
the maximum window time is maximum time to perform the trace processing without affecting behavioral processing performed by the information processing device,
the scheduled CDFG is divided into a plurality of control states,
the high-level synthesis processor further includes:
a state control machine generator to generate a state control machine indicating transition between the plurality of control states based on the scheduled CDFG; and
an execution trace mechanism generator to perform execution trace related information generation processing of generating execution trace mechanism circuitry, execution trace mechanism common circuitry, and an execution trace extension state control machine based on the execution trace specification description, the bound CDFG, the maximum window time, and the state control machine,
the execution trace mechanism common circuitry includes a clock counter and recording memory transfer circuitry for an execution trace recording memory,
the execution trace mechanism circuitry is a trace basic portion to perform the trace processing, and
the execution trace extension state control machine is information obtained by providing an execution trace extension function to the state control machine.

2.-4. (canceled)

5. The high-level synthesis device according to claim 1, wherein
the high-level synthesis processor further includes
a hardware description generator to generate the hardware descriptions based on the bound CDFG, the execution trace mechanism circuitry, the execution trace mechanism common circuitry, and the execution trace extension state control machine.

6. The high-level synthesis device according to claim 5 further comprising
a hardware description storage to store the hardware descriptions, wherein
the execution trace hardware description includes an execution trace mechanism circuitry description and an execution trace mechanism common circuitry description, and
the execution trace mechanism circuitry description is a hardware description corresponding to the execution trace mechanism circuitry, and the execution trace mechanism common circuitry description is a hardware description corresponding to the execution trace mechanism common circuitry.

7. The high-level synthesis device according to claim 6, wherein
the behavioral processing hardware description includes:
an execution trace extension hardware description obtained by associating the functional logic based on the behavioral description with a trace function; and
an execution trace extension state control machine description corresponding to the execution trace extension state control machine.

8. The high-level synthesis device according to claim 7, wherein
the behavioral description is described to correspond to a line number,
the execution trace specification description includes:
trace position identification information identifying a trace position in the behavioral description by the line number, the line number identified by the trace position identification information being defined as a trace target line number;
trace processing information indicating content of processing of recording trace information acquired when the trace processing is performed;
recording scheme information indicating a method of controlling the processing of recording the trace information; and
execution trace-time processing control information indicating whether to stop processing performed by the information processing device when the trace processing is performed, and
the trace processing information, the recording scheme information, and the execution trace-time processing control information are provided to correspond to the trace target line number.

9. The high-level synthesis device according to claim 8, wherein
the execution trace specification description further includes:
recorded variable information indicating a variable recorded as the trace information;
clock counter specifying information indicating whether to record a clock count value as the trace information; and
high-level synthesis control information indicating content of processing performed in a case where trace time to perform the trace processing exceeds the maximum window time, and
the recorded variable information, the clock counter specifying information, and the high-level synthesis control information are provided to correspond to the trace target line number.

10. The high-level synthesis device according to claim 9, wherein
the recording scheme information in the execution trace specification description includes:
a memory entry indicating types and the number of execution trace recording memories to record the trace information;
a size entry indicating a size of the execution trace recording memory;
a recording frequency entry indicating frequency of recording of execution trace information in the trace processing;
a full-time notification entry indicating whether to provide notification when the execution trace recording memory is in a memory full state;
a full-time operation entry indicating trace control content when the execution trace recording memory is in the memory full state; and
a data storage entry indicating a data storage destination to store the trace information in the execution trace recording memory.

11. The high-level synthesis device according to claim 10, wherein
the execution trace specification description further includes
pragma description information including a pragma description indicating content of the trace processing, and
the pragma description information is provided to correspond to the trace target line number.

12. The high-level synthesis device according to claim 10, wherein
the behavioral description has pragma description information in a line corresponding to the trace target line number, and the pragma description information includes a pragma description indicating content of the trace processing.

13. The high-level synthesis device according to claim 11, wherein
CDFG execution trace extension processing to acquire the CDFG with execution trace extension is performed by the CDFG execution trace extension processor to correspond to the trace target line number in the execution trace specification description, and includes the steps of:
(a) extracting, from the CDFG, a portion corresponding to the trace target line number as a line number-corresponding CDFG portion;
(b) identifying, from the line number-corresponding CDFG portion, the recorded variable indicated by the recorded variable information; and
(c) identifying an edge where execution processing to the trace target line number is confirmed in the behavioral description.

14. The high-level synthesis device according to claim 13, wherein
maximum window time calculation processing performed by the execution trace maximum window time calculator to calculate the maximum window time includes the steps of:
(a) identifying, from the bound CDFG, a recorded variable storage corresponding to the recorded variable corresponding to the trace target line number in the execution trace specification description; and
(b) calculating an update cycle of an update of stored content in the recorded variable storage as the maximum window time.

15. The high-level synthesis device according to claim 14, wherein
the execution trace related information generation processing performed by the execution trace mechanism generator includes generation basic processing and generation exception processing,
the generation basic processing includes the steps of:
(a) identifying a state of the state control machine in which the execution processing to the trace target line number corresponding to the trace target line number in the execution trace specification description is confirmed and performing extension processing of the state control machine when recording is completed;
(b) generating the execution trace mechanism common circuitry; and
(c) generating the execution trace mechanism circuitry corresponding to the trace target line number in the execution trace specification description and calculating a processing cycle of the generated execution trace mechanism circuitry,
the generation exception processing is performed in a case where the execution trace-time processing control information indicates that processing is not stopped and the processing cycle exceeds the maximum window time,
the generation exception processing includes the steps of:
(d) displaying a log including the trace target line number, the maximum window time, and the processing cycle; and
(e) performing one of error stop processing, rescheduling processing, and processing of changing content of the execution trace-time processing control information based on the high-level synthesis control information in the execution trace specification description, and
the error stop processing includes stopping of the high-level synthesis processing, and the rescheduling processing includes processing of causing the scheduling processor to generate the scheduled CDFG again.

16. The high-level synthesis device according to claim 15, wherein
the execution trace mechanism circuitry includes:
execution trace validity determination circuitry to determine validity of the trace processing;
target recorded variable acquisition circuitry to acquire a recorded variable value from the recorded variable storage;
clock counter acquisition circuitry to acquire the clock count value from the clock counter;
recorded entry creation circuitry to create information on the trace processing as a recorded entry based on the trace target line number, the recorded variable value, and the clock count value;
the execution trace recording memory satisfying the recording scheme information in the execution trace specification description;
recording frequency determination circuitry to determine the frequency of recording based on the recording scheme information;
a recording memory full state register indicating a state of capacity of the execution trace recording memory;
recording determination circuitry to determine whether to perform recording on the execution trace recording memory; and
notification mechanism circuitry to output a memory full signal indicating whether the execution trace recording memory is in the memory full state and a recording completion signal indicating whether recording on the execution trace recording memory is completed.

17.-24. (canceled)

25. A high-level synthesis device comprising:
a specification description provider to provide specification descriptions including a behavioral description indicating functional logic; and
a high-level synthesis processor to perform high-level synthesis processing of generating hardware descriptions based on the specification descriptions, the hardware descriptions including a behavioral processing hardware description for an information processing device obtained by hardware implementation of the functional logic indicated by the behavioral description, wherein
the specification descriptions further include an execution trace specification description for trace processing described to correspond to the behavioral description,
in the high-level synthesis processing, an execution trace hardware description describing an execution trace function to perform the trace processing is further generated based on the behavioral description and the execution trace specification description,
the hardware descriptions include the execution trace hardware description,
the execution trace specification description includes:
trace position identification information identifying a trace position in the behavioral description;
trace processing information indicating content of processing of recording trace information acquired when the trace processing is performed;
recording scheme information indicating a method of controlling the processing of recording the trace information; and
execution trace-time processing control information indicating whether to stop processing performed by the information processing device when the trace processing is performed, and
the trace processing information, the recording scheme information, and the execution trace-time processing control information are provided to correspond to the trace position identification information.

26. A high-level synthesis method comprising:
providing specification descriptions including a behavioral description indicating functional logic; and
performing high-level synthesis processing to acquire hardware descriptions based on the specification descriptions, the hardware descriptions including a behavioral processing hardware description for an information processing device obtained by hardware implementation of the functional logic described by the behavioral description, wherein
the specification descriptions further include an execution trace specification description for trace processing described to correspond to the behavioral description,
in the high-level synthesis processing, an execution trace hardware description indicating an execution trace function to perform the trace processing is further generated based on the behavioral description and the execution trace specification description,
the hardware descriptions include the execution trace hardware description,
the specification descriptions further include a high-level synthesis specification description defining high-level synthesis constraints,
performing the high-level synthesis processing includes:
creating a control data flow graph (CDFG) based on the behavioral description;
providing an execution trace extension function to the CDFG based on the execution trace specification description to acquire a CDFG with execution trace extension;
performing scheduling processing based on the high-level synthesis specification description on the CDFG with execution trace extension to acquire a scheduled CDFG;
allocating a hardware resource to the scheduled CDFG to acquire a bound CDFG; and
calculating maximum window time based on the bound CDFG,
the maximum window time is maximum time to perform the trace processing without affecting behavioral processing performed by the information processing device, the scheduled CDFG is divided into a plurality of control states,
performing the high-level synthesis processing further includes:
generating a state control machine indicating transition between the plurality of control states based on the scheduled CDFG; and
performing execution trace related information generation processing of generating execution trace mechanism circuitry, execution trace mechanism common circuitry, and an execution trace extension state control machine based on the execution trace specification description, the bound CDFG, the maximum window time, and the state control machine,
the execution trace mechanism common circuitry includes a clock counter and recording memory transfer circuitry for an execution trace recording memory,
the execution trace mechanism circuitry is a trace basic portion to perform the trace processing, and
the execution trace extension state control machine is information obtained by providing an execution trace extension function to the state control machine.

27. An information processing device implemented by the hardware descriptions generated by the high-level synthesis device according to claim 16, the information processing device comprising:
a behavioral processor hardware (HW) circuit and an execution trace extension state control machine HW circuit corresponding to the behavioral processing hardware description;
an execution trace mechanism circuitry HW circuit corresponding to the execution trace mechanism circuitry description; and
an execution trace mechanism common circuitry HW circuit corresponding to the execution trace mechanism common circuitry description.
